(19) United States
(12) Patent Application Publication
(10) Pub. No.: US 2008/0085604 A1
(43) Pub. Date: Apr. 10, 2008

(54) Plasma Treatment Method and Plasma Etching Method

(75) Inventors: Yasuyuki Hoshino, Kanagawa (JP); Seiji Samukawa, Miyagi (JP)

Correspondence Address: SUGHRUE MION, PLLC, 2100 PENNSYLVANIA AVENUE, N.W., SUITE 800, WASHINGTON, DC, 20037, US

(73) Assignees: SHOWA DENKO K.K., (JP); TOHOKU UNIVERSITY

(21) Appl. No.: 11/631,597

(22) PCT Filed: Jul. 6, 2005
(86) PCT No.: PCT/JP05/12878

§ 371 Date: Feb. 20, 2007

Related U.S. Application Data
(60) Provisional application No. 60/589,574, filed on Jul. 21, 2004.

(30) Foreign Application Priority Data
Jul. 7, 2004 (JP) 2004-200100
Mar. 28, 2005 (JP) 2005-091867

(51) Int. Cl. H01L 21/302

(52) U.S. Cl. 438/712; 438/710; 438/723; 438/724; 257/E21.214

(57) ABSTRACT

The present invention develops a process for plasma treatment using a gas having no greenhouse effect in order to realize global environmental preservation and sophistication of plasma process performance and provides a process for plasma etching with high accuracy which process can depress damage to devices. The process for plasma treatment according to the present invention comprises the steps of feeding a treatment gas containing fluorine gas (F₂) into a plasma generating chamber, alternately repeating application of high frequency electric field and stop of the application thereof to generate plasma, and carrying out substrate treatment by irradiating the plasma to a substrate. Furthermore, the substrate treatment may be carried out by individually or alternately extracting negative ions or positive ions from the plasma, or selectively extracting only negative ions, neutralizing them, to generate a neutral beam and irradiating the neutral beam to the substrate.

### CROSS REFERENCES OF RELATED APPLICATION

This application is an application filed under 35 U.S.C. §111(a) claiming benefit pursuant to 35 U.S.C. §119(e) of the filing date of Provisional Application 60/589, 574 filed on Jul. 21, 2004, pursuant to 35 U.S.C. §111(b).

### TECHNICAL FIELD

The present invention relates to a plasma treatment process for treating a substrate using plasma generated utilizing a high frequency electric field, and relates to a plasma etching process suitable for fine processing in production of semiconductor elements and micro machine (MEMS: Micro Electric Mechanical System) elements.

### TECHNICAL BACKGROUND

In plasma processes used for dry etching during the production processes of semiconductor integrated circuits, large amounts of fluorocarbon type or inorganic fluoride type gases, (for example, carbon tetrafluoride gas (CF₄), sulfur hexafluoride gas (SF₆), or the like) are used. However, the fluorocarbon type and inorganic fluoride type gases are greenhouse effect gases having a high global warming potential (GWP), and a large factor in inducing global warming together with carbon dioxide. Accordingly, in order to decrease the emission of the greenhouse effect gases to the environment, the development of a new process for using alternative gases in place of the fluorocarbon type and inorganic fluoride type gases has been desired urgently.

In the production processes of semiconductor integrated circuits, since recently, the processing patterns have been remarkably minute, the development on dry etching technique having high accuracy (high selectivity, high aspect ratio and high rate) has been demanded greatly.

It is considered that the mechanism of plasma etching using a plasma process is classified into the following three groups: (1) etching with radicals, (2) etching with reactive ions and (3) ion assist etching (etching with both of ions and radicals).

The mechanism (1) has a merit of having excellent etching selectivity to various kinds of materials because the radical reaction is pure chemical reaction. However, because radicals are electrically neutral, radicals to be entered into a substrate are reached by diffusion and the movement direction thereof to the substrate is at random, so that etching reaction on the substrate surface progresses to every direction. Therefore, when the substrate is etched with radicals, etching progresses until the under part of an etching mask, that is, the mechanism (1) has a problem in that isotropic etching is performed.

In the mechanism (2), because ions are particles having electric charge, ions are accelerated to a substrate by an electric field from the outside to make ions to have directionality. Examples of such etching process with accelerated ions may include physical sputtering and chemical sputtering.

The physical sputtering is carried out by cutting the bonding of substrate atoms with giving the momentum of ions to the substrate atoms and going out to a gas phase. Meanwhile, the chemical sputtering is carried out in such a way that reactive ions entered into the substrate surface and substrate atoms cause to chemical reaction by incident energy, and thereby a reaction product is released into a gas phase.

In the etching process using reactive ions, it is considered that the physical sputtering and the chemical sputtering are simultaneously caused on the substrate surface. Since incident ions to be entered are almost vertical to a substrate, the etching form is formed almost vertically to an etching mask, that is, anisotropic etching can be attained. However, the etching selectivity with a mask material or a base material is remarkably lowered as compared with the etching with radicals.

The ion assist reaction in the mechanism (3) largely depends on ion energy because it is caused by irradiating accelerated ions on radicals adsorbed on the surface of a substrate to be etched. The reaction mainly takes place on the part where ions are irradiated and thereby the etching form is anisotropic etching.

It is considered that the etching processes of the mechanisms (1) to (3) simultaneously take place in a certain proportion in the plasma etching using the plasma process. On the actual etching surface, deposition of reaction products or polymerization due to gases (polymerization reaction) occurs except for the above etching reaction. The proportion of these surface reaction process in the etching reaction is largely changed by operation conditions (gas kind, pressure, power or the like) during the etching and thereby etching properties such as etching rate, etching form and etching selectivity are largely changed. Progressing the high integration of semiconductor devices, it is earnestly demanded to control these complicated etching phenomena, increase the contribution of ions to the etching reaction and thereby improve the fine processing.

The plasma process is necessary and indispensable as dry etching technique for semiconductors, however, damage on devices caused by the plasma process is induced in accordance with fining processing patterns. Particularly, in highly technological processes such that processing patterns are fined to a size of not more than 0.1 μm, damage caused by irradiation with electric charges (electron, ion), light quantum (photon) and the like generated in plasma causes, for example, dielectric breakdown of a gate insulating film and abnormality of processing forms so that it exerts serious influences on device properties. New materials called as high-k and low-k films have been actively studied and developed with the aim of enhancing the semiconductor device performance and saving electricity consumption, but they are physically and chemically unstable as compared with the silicon oxide (SiO₂) films now in use so that it is considered that the damages caused by the plasma processing will be more remarkable. Therefore, in order to promote the examination in practical use of the high-k and low-k films, the development of new plasma processing has been earnestly demanded.

With the aim of avoiding the device damage caused by plasma processing, techniques for controlling particles (electron, ion, radical and photon) in plasma have been variously developed. The plasma control can be attained by, for example, (1) a pulse-time-modulated plasma generation technique such that high frequency electric field application and stop of the application are repeated in several ten μsec order alternately and thereby the processing gas is plasmatized, and (2) a neutral beam generating technique such that positive ions and negative ions in plasma are neutralized to generate beams having uniform directionalities.

In the pulse-time-modulated plasma generation technique as shown in JP-A-6-267900 or JP-A-8-181125, when high frequency electric field application and stop of the application are repeated in several ten μsec order alternately, during the application, positive ions and radicals are generated, while during the stop of the application, negative ions are generated with keeping positive ions and radicals. The pulse-time-modulated plasma generation technique has a property such that negative ions, which are hardly generated by conventional continuous discharged plasma, can be generated in large amounts.

In the neutral beam generation technique, ions generated in plasma accelerated by application with voltage and are passed through an electrode having many fine pores and thereby neutralized. As a result, neutral beams having uniform polarities can be generated.

Furthermore, utilizing an apparatus as shown in, for example, JP-A-9-139364, large amounts of negative ions generated in pulse-time-modulated plasma is selectively accelerated and neutralized by the combined use of the pulse-time-modulated plasma generation technique and the neutral beam generation technique so that neutral beams having uniform polarities can be generated with high density. Since the neutralization of negative ions progresses by separation of electrons adhered on gas atoms and molecules, a neutral beam having a high efficiency can be generated with low energy as compared with neutralization of positive ions by electric exchange.

It has been reported that when etching is carried out utilizing beams, which are generated by such a process, consisting only neutral particles necessary for etching reaction, it is possible to avoid irradiation with electric particles and photons in plasma and to control device damage caused by the plasma processing.

In order to completely control particles (electron, ion, radical and photon) in plasma during the plasma processing and practically use plasma etching with high accuracy which etching depresses the damage to devices, it is an important problem to optimize the operating conditions (gas kind, pressure, power and the like) in addition to the improvement of a plasma generating apparatus and a neutral beam generating apparatus. The gas kind used in plasma generation has the following problems.

In the semiconductor devices, since a silicon oxide (SiO₂) is used as a film of insulating between electrodes, it is necessary and indispensable to form contact holes for contacting electrodes with elements and lower electrodes. In the formation of such contact holes, fluorocarbon gas has been used conventionally because it is important to prepare high selectivity to Si, which is used for a substrate.

In plasma with such fluorocarbon gas, deposition (polymerization) of a polymer is caused on the substrate surface. Accordingly, in most plasma processings based on halogen, the Si substrate tends to be etched more rapidly than the SiO₂ substrate, so that the competition of the polymer deposition and the etching reaction is induced on both of the SiO₂ surface and the Si surface. However, because O (oxygen) is present in the SiO₂ layer, oxygen dissociates during SiO₂ etching, is bonded to a deposited polymer, to form a volatile product, e.g. CO, CO₂ or COF₂ molecules and further polymerization of the deposited polymer is depressed on the SiO₂ layer. Meanwhile, because the Si film free from oxygen has no polymerization film deposition-depressing effect on the surface thereof, deposition of a polymer is induced. By this effect that the deposited polymer protects (masks) the Si surface, it is possible to obtain the etching selectivity to the substrate.

As described above, fluorocarbon gas, however, has a problem of having a high global warming potential. Therefore, it is desired to attain etching with high selectivity without using such fluorocarbon gas. For the attaining the etching, it is necessary to develop a novel process without using the protective effect of a deposited polymer derived from fluorocarbon gas.

For example, it is considered that if plasma can be generated using a gas having no greenhouse effect and irradiated on a substrate by controlling the energy and density of ions or neutral beams in the plasma with high accuracy, it will be possible to completely control the reaction rate and the selectivity of etching and also to realize the process capable of forming favorable contact holes. Simultaneously, it is also considered that irradiation damage caused by electric charges (electron, ion) and light quantum (photon) generated in the plasma is depressed, and the above described dielectric breakdown of an insulating film and abnormality of processing form thereof can be avoided.

Meanwhile, in silicon (Si) etching used for electrodes or the like of semiconductor devices, the reaction with radical is depressed using a Cl (chlorine) type gas or a Br (bromine) type gas rather than a F (fluorine) type gas and thereby anisotropic etching is attained. In the F type gas using processing, the F radicals reached to the Si substrate intrude into the inside of a Si lattice to form an adsorbing layer having a thickness of about 6 atoms. Contrarily, in the processing using the Cl type or Br type gas, because the Cl radical or Br radical is larger as compared with the Si lattice distance, the Cl radical or Br radical hardly intrudes into the inside of the Si lattice and the adsorbing layer has a thickness of about one atom. Therefore, F radical has higher reactivity with Si as compared with Cl radical or Br radical. Consequently, the case of carrying out Si etching using conventional plasma processing has a problem in that when the F type gas is used, the etching rate is high but anisotropic etching cannot be attained.

Accordingly, in order to enable high rate etching using the F type gas and attain anisotropic etching, the proportion of F radical having a random movement direction to a substrate is decreased and also it is necessary to develop a novel process for generating F ion and neutral F beam which enter in a direction vertical to the substrate, with a high density. Further, in such novel process, it is considered that dielectric breakdown of an insulating film (SiO₂ which is a substrate film of Si, high-k or the like) and abnormality of processing form, as described above, can be avoided.

Moreover, in the production process of micro machine (MEMS: Micro Electric Mechanical System) devices which have rapidly been examined to practically use in recent years, as a fine processing, etching processing is required to form grooves having a depth of several 10 μm and not less than to 100 μm used in a mechanical structure on a Si substrate. In such a process, plasma etching technique is also applied and the requirements to etching properties are mainly the following three articles.

(1) The high etching rate can be attained.

(2) The verticality of an etching profile can be attained.

(3) The etched wall surface has excellent smoothness.

The two properties described in the requirements (1) and (2) essentially have a trade-off relation. The reason is as follows. In order to attain the high etching rate, in general, it is necessary to generate F radical in a high concentration in plasma, but in the etching mainly with radical, the verticality (anisotropy) of the etching profile cannot be obtained.

At present, in order to solve this problem, a Bosch process is widely used that one cycle comprising an isotropic etching process and a process of forming a film for protecting a sidewall is repeated.

In the Bosch process, at first, during the etching processing, Si isotropic etching is caused due to F radical generated from SF₆ gas plasma. Next, during film forming processing, a fluorocarbon like polymer film is formed by fluorocarbon type gas (C₄F₈ or the like) plasma. In this forming, the polymer film is deposited on all the surfaces (the bottom parts and sidewall parts of a trench). In the next etching processing which is repeated again, only the bottom parts of the trench in the polymer film formed by the prior stage is selectively removed by receiving ion charge. Meanwhile, during the etching processing, since the polymer film deposited on the sidewall parts of the trench does not receive ion charge, the polymer film is protected from etching and remained. In the etching processing, the ion charge is induced only in the bottom part of the trench based on the reason that a high frequency electric field or the like is applied on the electrode disposed on the lower part of the substrate and thereby ions (charged particles) in plasma is accelerated in a direction vertical to the substrate. The process composed of such two processings (isotropic etching processing and film forming processing for protecting sidewall) is repeated per a period of time of several sec to several 10 sec and thereby a certain extent of the high etching rate and the verticality of etching profile can be realized.

However, because etching does not proceed at all during the film forming processing, the Bosch process has two problems such that the etching rate is limited and step like configuration, called as scallop is formed on the sidewall parts, namely the surface roughness is formed. The Si isotropic etching will cause the bumps of the scallop. Therefore, when the etching rate is intended to be increased by prolonging each etching time or increasing the F radical concentration in plasma, the bumps of the scallop are further increased.

Accordingly, in the Bosch process, the smoothness of the sidewall parts and the etching rate are in a tradeoff relation. Presently, in order to improve properties of devices such as MEMS or the like, a technique of decreasing the bumps of the scallop as small as possible has been developed.

In the meantime, various high rate etching processes capable of not causing scallop bumps have been proposed without carrying out the special film forming processing for protecting sidewalls, which is carried out in the Bosch process. For example, JP-A-2002-93776 and JP-A-2004-87738 disclose a process for carrying out substrate treatment by generating plasma of SF₆ gas mixed with O₂ gas, C₄F₈ gas or SiF₄ gas.

In the process using this mixed gas, however, the high etching rate and the smoothness of the etching surface are maintained and also the verticality of the etching form can be improved in an certain extent, but it is difficult to attain such a high verticality having etching profile that can be obtained by the Bosch process.

Namely, conventional techniques cannot simultaneously satisfy the three requirements for processing technique including the article (1) such that the high etching rate can be attained, the article (2) such that the verticality of an etching profile can be attained and the article (3) such that the etched wall surface has excellent smoothness.

Furthermore, as described above, the fluorocarbon type gases such as SF₆ gas, C₄F₈ gas or the like have a problem of having a high global warming potential. Therefore, the development of a novel process capable of realizing fine processing with high performance without using these greenhouse effect gases has been demanded strongly. For example, if plasma can be generated using gases having no greenhouse effect and irradiated on a substrate by controlling the energy and the density of ions and neutral beams in plasma with high accuracy, it is possible to simultaneously satisfy the three requirements for processing technique including the article (1) such that the etching can attain a high etching rate, the article (2) such that the verticality of an etching profile can be attained and the article (3) such that the etched wall surface has excellent smoothness.

### DISCLOSURE OF INVENTION

It is an object of the invention to develop a plasma processing process using a gas having no greenhouse effect and to provide a plasma etching process with high accuracy capable of depressing damage to devices, in order to realize the global environmental preservation and the advancement of plasma process performance.

The present inventor have been earnestly studied to solve the above problems and succeeded in developing the process for plasma processing process with high accuracy utilizing a gas having no greenhouse effect for the first time.

The present invention relates the following items.

(1) A process for plasma treatment comprises the steps of feeding a treatment gas containing a fluorine gas (F₂) into a plasma generating chamber, alternately repeating application of a high frequency electric field and stop of the application thereof to generate plasma, and carrying out substrate treatment by irradiating the plasma to a substrate.

(2) A process for plasma treatment comprises the steps of feeding a treatment gas containing a fluorine gas (F₂) into a plasma generating chamber, alternately repeating application of a high frequency electric field and stop of the application thereof to generate plasma, individually or alternately extracting negative ions or positive ions from the plasma and neutralizing them to generate a neutral beam, and carrying out substrate treatment by irradiating the neutral beam to a substrate.

(3) A process for plasma treatment comprises the steps of feeding a treatment gas containing a fluorine gas (F₂) into a plasma generating chamber, alternately repeating application of a high frequency electric field and stop of the application thereof to generate plasma, selectively extracting only negative ions from the plasma and neutralizing them to generate a neutral beam, and carrying out substrate treatment by irradiating the neutral beam to a substrate.

(4) The process for plasma treatment according to any one of the items (1) to (3), wherein the treatment gas is 100% by volume of fluorine gas (F₂).

(5) The process for plasma treatment according to any one of the items (1) to (3), wherein the treatment gas is a mixed gas of fluorine gas (F₂) and chlorine gas (Cl₂).

(6) The process for plasma treatment according to any one of the items (1) to (5), wherein the fluorine gas (F₂) is fluorine gas (F₂) generated by thermally decomposing a solid metal fluoride.

(7) The process for plasma treatment according to any one of the items (1) to (6), wherein in the generating the plasma, the gas pressure of a plasma generating chamber is from 0.1 to 100 Pa.

(8) The process for plasma treatment according to any one of the items (1) to (7), wherein in the generating the plasma, the stop time of the application of high frequency electric field is from 20 to 100 μsec.

(9) A process for fluorination treatment which process is characterized by utilizing the process for plasma treatment as described in any one of the items (1) to (8).

(10) A process for plasma etching a substrate which process is characterized by utilizing the process for plasma treatment as described in any one of the items (1) to (8).

(11) A process for plasma etching silicon or a silicon compound which process is characterized by utilizing the process for plasma etching as described in the item (10).

(12) The process for plasma etching according to the item (11) wherein the silicon compound comprises silicon oxide, silicon nitride or a silicate.

(13) The semiconductor device produced by the process as described in any one of the items (1) to (12).

(14) The micro machine (MEMS: Micro Electric Mechanical System) device produced by the process as described in any one of the items (1) to (12).

### EFFECT OF THE INVENTION

Using the plasma treatment process by use of a gas having no greenhouse effect according to the present invention, the plasma etching treatment with high accuracy suitable for fine processing in production of semiconductor devices can be attained. Particularly, from plasma, only neutral beams necessary for etching reaction are taken out and are irradiated on a substrate and thereby the production process for coming generation semiconductor devices in which processing patterns are finned into a size of not more than 0.1 μm can be realized. Furthermore, the production process is effective as a fine processing technique in the production of MEMS devices and the like which have recently been developed.

### BRIEF DESCRIPTION OF DRAWINGS

FIG. 1 is a schematic view (example 1) showing one embodiment of a pulse-time-modulated plasma generating apparatus capable of carrying out the plasma treatment process and the plasma etching process according to the present invention.

FIG. 2 is a schematic view (example 2) showing one embodiment of a pulse-time-modulated plasma generating apparatus capable of carrying out the plasma treatment process and the plasma etching process according to the present invention.

FIG. 3 is a schematic view showing one embodiment of a neutral beam generating apparatus capable of carrying out the plasma treatment process and the plasma etching process according to the present invention.

FIG. 4 is a schematic view showing a plasma and neutral beam analysis apparatus used in experiments of Example 1 and Comparative Example 1.

FIG. 5 is a QMS spectrum of negative ions in continuous plasma [RF bias=500 W] and pulse-time-modulated plasma [RF bias=2 kW (during the ON time)] in the case of using fluorine gas (F₂) as a treatment gas according to Example 1.

FIG. 6 is a QMS spectrum of negative ions in continuous plasma [RF bias=1 kW] and pulse-time-modulated plasma [RF bias=1 kW (during the ON time)] in the case of using fluorine gas (F₂) as a treatment gas according to Example 1.

FIG. 7 is a result of measuring an electron density in continuous plasma in each of the case of using fluorine gas (F₂) and the case of using sulfur hexa-fluoride gas (SF₆) as a treatment gas according to Example 1 and Comparative Example 1.

FIG. 8 is a result of measuring an F radical amount in continuous plasma in each of the case of using fluorine gas (F₂) and the case of using sulfur hexa-fluoride gas (SF₆) as a treatment gas according to Example 1 and Comparative Example 1.

FIG. 9 is an image observed with SEM concerning to a substrate (silicon surface provided with aluminum pattern) etched by pulse-time-modulated plasma generated using fluorine gas (F₂) as a treatment gas according to Example 2.

FIG. 10 shows QMS spectrums of negative ion in pulse-time-modulated plasma generated using fluorine gas (F₂) as a treatment gas and residual negative ion in neutral beam generated by selectively extracting negative ion from the plasma according to Example 1.

FIG. 11 is a result of measuring the total flux of neutral beam generated by selectively extracting negative ion from pulse-time-modulated plasma in each of the case of using fluorine gas (F₂) and the case of using sulfur hexa-fluoride gas (SF₆) as a treatment gas according to Example 1 and Comparative Example 1.

FIG. 12 is an image observed with SEM concerning to a substrate (polysilicon surface provided with resist pattern) etched by neutral beam in the case of selectively extracting negative ions with the use of the carbon made electrode for extracting beam from pulse-time-modulated plasma generated using fluorine gas (F₂) as a treatment gas according to Example 3.

FIG. 13 is an image observed with SEM concerning to a substrate (polysilicon surface provided with resist pattern) etched by neutral beam in the case of selectively extracting negative ions with the use of the carbon made electrode having an alumina sprayed surface for extracting beam from pulse-time-modulated plasma generated using fluorine gas (F₂) as a treatment gas according to Example 3.

FIG. 14 is an image observed with SEM concerning to a substrate (polysilicon surface provided with resist pattern having a line width of 50 nm) etched by neutral beam generated by selectively extracting negative ions from pulse-time-modulated plasma generated using fluorine gas (F₂) as a treatment gas according to Example 4.

FIG. 15 is a QMS spectrum of negative ions in pulse-time-modulated plasma in each of the case of using fluorine gas (F₂) and the case of using sulfur hexa-fluoride gas (SF₆) as a treatment gas according to Example 1 and Comparative Example 1.

FIG. 16 is an image observed with SEM concerning to a substrate (silicon surface provided with aluminum pattern) etched by pulse-time-modulated plasma generated using sulfur hexa-fluoride gas (SF₆) as a treatment gas according to Comparative Example 2.

FIG. 17 is an image observed with SEM concerning to a substrate (polysilicon surface provided with resist pattern) etched by neutral beam in the case of selectively extracting negative ions with the use of the carbon made electrode for extracting beam from pulse-time-modulated plasma generated using sulfur hexa-fluoride gas (SF₆) as a treatment gas according to Comparative Example 3.

FIG. 18 is an image observed with SEM concerning to a substrate (polysilicon surface provided with resist pattern) etched by neutral beam in the case of selectively extracting negative ions with the use of the carbon made electrode having an alumina sprayed surface for extracting beam from pulse-time-modulated plasma generated using sulfur hexa-fluoride gas (SF₆) as a treatment gas according to Comparative Example 3.

FIG. 19 is an image observed with SEM concerning to a substrate (polysilicon surface provided with resist pattern having a line width of 50 nm) etched by neutral beam generated by selectively extracting negative ions from pulse-time-modulated plasma generated using sulfur hexa-fluoride gas (SF₆) as a treatment gas according to Comparative Example 4.

### DESCRIPTION OF REFERENCE NUMERALS

1 Treatment gas
2 Quartz made plasma generating and substrate treatment chamber
3 Antenna for generating inductively coupled plasma
4 High frequency electric source for generating plasma capable of pulse-time-modulation
5 Plasma
6 Carbon made upper part electrode for accelerating ion
7 Electric source for voltage application (for upper part electrode)
8 Carbon made lower part electrode for accelerating ion
9 Electric source for voltage application (for lower part electrode)
10 Substrate holding base
11 Substrate
12 Exhaust gas
21 Treatment gas
22 Quartz made plasma-generating chamber
23 Antenna for generating inductively coupled plasma
24 High frequency electric source for generating plasma capable of pulse-time-modulation
25 Plasma
26 Carbon made upper part electrode for accelerating ion
27 Electric source for voltage application (for upper part electrode)
28 Carbon made lower part electrode for accelerating ion (electrode for extracting beam)
29 Electric source for voltage application (for lower part electrode)
30 Stainless steel made substrate treatment chamber
31 Neutral beam
32 Substrate holding base
33 Substrate
34 Exhaust gas
41 Treatment gas
42 Quartz made plasma-generating chamber
43 Antenna for generating inductively coupled plasma
44 High frequency electric source for generating plasma capable of pulse-time-modulation
45 Plasma
46 Carbon made upper part electrode for accelerating ion
47 Electric source for voltage application (for upper part electrode)
48 Carbon made lower part electrode for accelerating ion (electrode for extracting beam)
49 Electric source for voltage application (for lower part electrode)
50 Stainless steel measuring chamber
51 Neutral beam
52 Measuring apparatus
53 Exhaust gas
61 Treatment gas
62 Plasma generating and substrate treatment chamber
63 Antenna for generating inductively coupled plasma
64 High frequency electric source for generating plasma capable of pulse-time-modulation
65 Plasma
68 Carbon made electrode for accelerating ion
69 Electric source for voltage application
70 Substrate holding base
71 Substrate
72 Exhaust gas

### BEST MODE FOR CARRYING OUT THE INVENTION

The process for plasma treatment and the plasma etching process using the treatment process according to the present invention will be described in detail hereinafter.

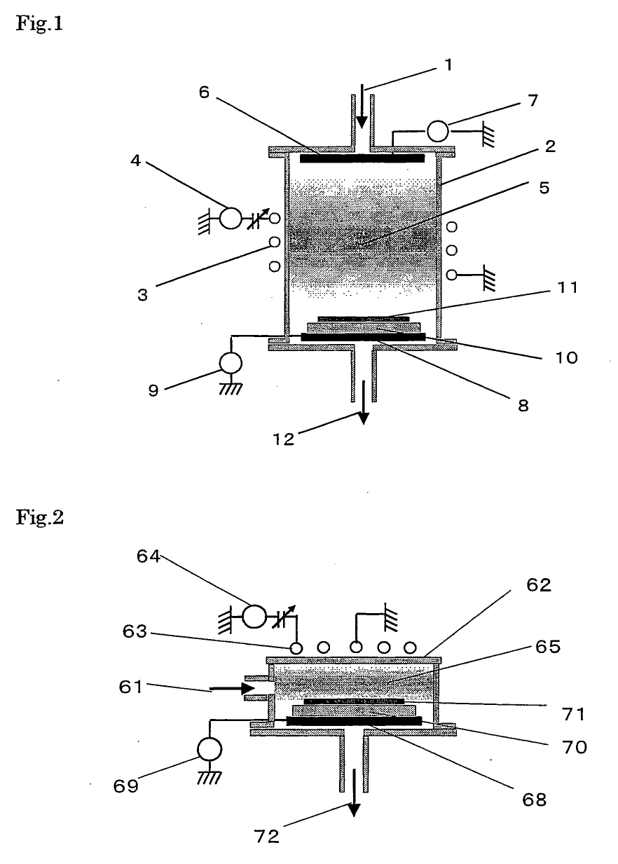

One example of a pulse-time-modulated plasma generating apparatus capable of carrying out the plasma treatment process and the plasma etching process according to the present invention is shown in FIG. 1. The structure of the pulse-time-modulated plasma generating apparatus as shown in FIG. 1 is described below.

In the pulse-time-modulated plasma generating apparatus as shown in FIG. 1, an antenna 3 for generating inductively coupled plasma is rolled up in a coil-like state into the outer periphery of a plasma generating and substrate treatment chamber 2 made of quartz provided with a port for feeding a treatment gas 1, and the antenna 3 is connected with a high frequency electric source 4 for generating plasma capable of pulse-time-modulation.

Applying a high frequency electric field from the outside of the plasma generating and substrate treatment chamber 2 in which the treatment gas 1 has been fed, plasma 5 is generated in the plasma generating and substrate treatment chamber 2. Continuously applying a high frequency electric field generates usual plasma (hereinafter referred to continuous plasma), and alternately repeating the application of a high frequency electric field and the stop of the application can generate pulse-time-modulated plasma. The application of a high frequency electric field and the stop of the application can be carried out by, for example, applying RF bias having a discharge frequency of 13.56 MHz in a pulse state from the high frequency electric source 4 to the antenna 3. The alternate repeating time (pulse width) of the application of a high frequency electric field and the stop of the application can be arbitrarily determined.

Further, on the upper and lower parts inside the plasma generating and substrate treatment chamber 2, a carbon-made upper part electrode 6 for accelerating ions and a carbon-made lower part electrode 8 for accelerating ions are provided and are connected to an electric source for voltage application (for upper part electrode) 7 and an electric source for voltage application (for lower part electrode) 9, respectively.

Utilizing the potential difference between the voltage applied on the upper part electrode 6 and the voltage applied on the lower part electrode 8, ions generated in plasma 5 (positive or negative charged particles) are accelerated in a direction almost vertical to a substrate 11 disposed on a substrate holding base 10 in the plasma generating and substrate treatment chamber 2 and are irradiated almost vertically to the substrate 10. The above substrate holding base 10 can be cooled by a cooling apparatus (not shown).

The plasma generating and substrate treatment chamber 2 is exhausted by an exhaust pump (not shown), and exhaust gas 12 is subjected to non-toxicity treatment by an exhaust gas treatment apparatus (not shown) and is exhausted outside the system.

One example of the pulse-time-modulated plasma generating apparatus capable of carrying out the plasma treatment process and the plasma etching process according to the present invention is shown in FIG. 2. The structure of the pulse-time-modulated plasma generating apparatus as shown in FIG. 2 is described below.

In the pulse-time-modulated plasma generating apparatus as shown in FIG. 2, an antenna 63 for generating inductively coupled plasma is rolled up in a spiral state on the upper surface of a plasma generating and substrate treatment chamber 62 provided with a port for feeding a treatment gas 61, and the antenna 63 is connected with a high frequency electric source 64 for generating plasma capable of pulse-time-modulation.

Applying a high frequency electric field from the outside of the plasma generating and substrate treatment chamber 62 in which the treatment gas 61 has been fed, plasma 65 is generated in the plasma generating and substrate treatment chamber 62. Continuously applying a high frequency electric field generates continuous plasma, and alternately repeating the application of a high frequency electric field and the stop of the application can generate pulse-time-modulated plasma. The application of a high frequency electric field and the stop of the application can be carried out by, for example, applying RF bias of 13.56 MHz in a pulse state as a discharge frequency from the high frequency electric source 64 to the antenna 63. The alternate repeating time (pulse width) of the application of a high frequency electric field and the stop of the application can be arbitrarily determined.

Further, on the lower part of a substrate holding base 70, an electrode 68 for accelerating ions is provided and is connected with an electric source 69 for voltage application. The above substrate holding base 70 can be cooled by a cooling apparatus (not shown). Furthermore, the height of the substrate 61, namely the distance between the substrate and plasma generating part can be changed by an elevating apparatus (not shown).

The inside of the plasma generating and substrate treatment chamber 62 is exhausted by an exhaust pump (not shown), and exhaust gas 72 is subjected to non-toxicity treatment by an exhaust gas treatment apparatus (not shown) and is exhausted outside the system.

The first process of the present invention is a plasma treatment process, which comprises the steps of feeding a treatment gas containing fluorine gas (F₂) to a plasma generating chamber, alternately repeating the application of a high frequency electric field and the stop of the application to generate plasma, and irradiating the plasma to a substrate and thereby carrying out substrate treatment, using, for example, a pulse-time-modulated plasma generating apparatus as shown in FIGS. 1 and 2. The present inventors have succeeded in generating pulse-time-modulated plasma of fluorine gas (F₂) for the first time.

In the pulse-time-modulated plasma of fluorine gas (F₂) obtained by the above process, the amount of negative ions (F⁻) generated is remarkably larger as compared with continuous plasma. The amount of negative ions (F⁻) generated in the pulse-time-modulated plasma of fluorine gas (F₂) is also remarkably larger as compared with the case of using sulfur hexa-fluoride gas (SF₆) as a treatment gas which case has been studied conventionally.

It is confirmed that the electron density of continuous plasma of fluorine gas (F₂) is remarkably higher as compared with the electron density of continuous plasma of sulfur hexa-fluoride gas (SF₆) with the results of measuring the electron density of the plasma. The fact that the electron density of the plasma is higher shows that the ionization effect of a treatment gas is high, and it is considered that the properties of such fluorine gas (F₂) are causes of generating large amounts of negative ions (F⁻) in the pulse-time-modulated plasma. That is, presumed is such a schema that high density electron generated during ON time of the high frequency electric field in the pulse-time-modulated plasma is dissociatively attached to fluorine gas (F₂) during OFF time of the following high frequency field to generate large amounts of negative ions (F⁻).

In the pulse-time-modulated plasma of fluorine gas (F₂), the amount of generated radical (F) having no directionality, which radical hinders fine processing, is remarkably lower as compared with the case of using sulfur hexa-fluoride (SF₆), which has been studied conventionally, as a treatment gas.

Accordingly, in the pulse-time-modulated plasma using fluorine gas (F₂) as a treatment gas, negative ions (F⁻) generated in large amounts are accelerated toward the substrate by means of an electric field from the outside, so as to have a directionality and because the amount of radical (F) having no directionality generated is low, the desired anisotropic etching can be realized.

Although fluorine gas (F₂) is a gas, which global warming potential (GWP) is zero, without greenhouse effect, the practical use thereof has scarcely been studied for plasma treatment technique and plasma etching treatment technique until now. As the reasons, the first one is that the handling of fluorine gas (F₂) is difficult because of having very high reactivity, corrosion and toxicity, and the second one, which is conventionally known, is that when plasma due to fluorine gas (F₂) is generated by a conventional process, anisotropic etching, which is an important etching property, cannot be realized.

The process of the present invention is characterized by using a gas containing fluorine gas (F₂) as a treatment gas, based on the background of the following technical progress. That is, in production process of semiconductor devices or the like, it has been possible to use fluorine gas (F₂) having high reactivity, corrosion resistance and toxicity as a processing gas, accompanying with recent new development of materials having excellent corrosion resistant and advancement of reliability and safety in gas feeding equipment. Based on such technical background, the present inventors first applied fluorine gas (F₂) to pulse-time-modulated plasma and first found that pulse-time-modulated plasma of fluorine gas (F₂) has excellent fine processability, which is a specific property such that the amount of ions generated is large and the amount of radicals generated is small. As a result, the present inventors first could make high rate anisotropic etching process with plasma using fluorine gas (F₂) into practical use.

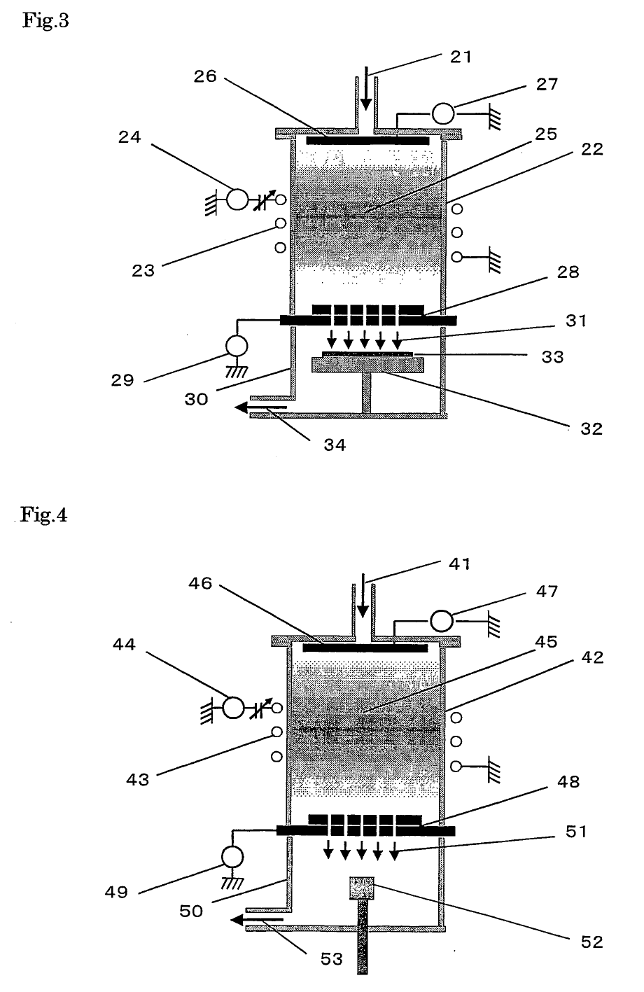

Next, one example of a neutral beam generating apparatus capable of carrying out the plasma treatment process and the plasma etching process according to the present invention is shown in FIG. 3. The structure of the neutral beam generating apparatus as shown in FIG. 3 is described below.

In the neutral beam generating apparatus as shown in FIG. 3, a quartz made plasma generating chamber 22 has the same structure as that of the quartz made plasma generating and substrate treatment chamber 2 in the pulse-time-modulated plasma generating apparatus as shown in FIG. 1. In the plasma generating chamber 22, a port for feeding a treatment gas 21 is provided and an antenna 23 for generating inductively coupled plasma is rolled up in a coil-like state into the outer periphery of the plasma generating chamber 22 and the antenna 23 is connected with a high frequency electric source 24 for generating plasma capable of pulse-time-modulation. Plasmas 25 (continuous plasma and pulse-time-modulated plasma) can be generated by, for example, applying RF bias having an discharge frequency of 13.56 MHz from the high frequency electric source 24 to the antenna 23.

Further, on the upper and lower parts inside the plasma generating chamber 22, a carbon-made upper part electrode 26 for accelerating ions and a carbon-made lower part electrode 28 for accelerating ions (electrode for extracting a beam) are provided and are connected to an electric source for voltage application (for upper part electrode) 27 and an electric source for voltage application (for lower part electrode) 29, respectively.

Utilizing the potential difference between the voltage of the upper part electrode 26 and the voltage of the lower part electrode 28, ions generated in plasma 25 (positive or negative charged particles) is accelerated in a direction almost vertical to a substrate 33 disposed on a substrate holding base 32 inside the a stainless steel made substrate treatment chamber 30 and is irradiated to the substrate 33 almost vertically.

In order to neutralize the ion which is accelerated and extracted from the plasma 25, a plurality of fine pores, for example, pores having a diameter of 1 mm and a depth of 10 mm are provided on the lower part electrode 28. The ions accelerated by the potential difference of the voltage applied on the upper part electrode 26 and the lower part electrode 28 is neutralized by electric charge exchange or electronic separation during passing through the fine pores of the lower part electrode 28, and thereby a neutral beam 31 is generated. The neutral beam 31 is irradiated almost vertically to the substrate 33. Further, the above substrate holding base 32 can be cooled by a cooling apparatus (not shown) and the height of the substrate 33, namely the distance between the substrate and plasma generating part can be changed by an elevating apparatus (not shown).

The inside of the substrate treatment chamber 30 is exhausted by an exhaust pump (not shown), and exhaust gas 34 is subjected to non-toxicity treatment by an exhaust gas treatment apparatus (not shown) and is exhausted outside the system.

The second process of the present invention is a plasma treatment process, which comprises the steps of feeding a treatment gas containing fluorine gas (F₂) to a plasma generating chamber, alternately repeating the application of a high frequency electric field and the stop of the application to generate plasma, separately or alternately extracting negative ions or positive ions from the plasma and neutralizing them to generate a neutral beam, and irradiating the neutral beam to the substrate and thereby carrying out substrate treatment, using, for example, a neutral beam generating apparatus as shown in FIG. 3.

As described above, the present inventors first succeeded in generating pulse-time-modulated plasma of fluorine gas (F₂), and found that in the pulse-time-modulated plasma using fluorine gas (F₂) as a treatment gas, the amount of generated negative ions (F⁻) capable of giving directionality is remarkably large and the amount of generated radical (F) not having directionality is remarkably low.

However, the pulse-time-modulated plasma generating apparatus as shown in FIG. 1 described in the first process of the present invention has a problem such that, since the plasma generating chamber and the substrate treatment chamber are united in one, anisotropic etching can be realized but the damage caused by irradiating charging particles and a photon generated in the plasma to the substrate is unavoidable.

Meanwhile, in the neutral beam generating apparatus as shown in FIG. 3 described in the second process of the present invention, negative ions or positive ions are separately or alternately extracted from pulse-time-modulated plasma of fluorine gas (F₂) and neutralized to generate a neutral beam necessary for etching process and the beam is irradiated to substrate. Therefore, anisotropic etching wherein the damage caused by irradiating charging particles and photon generated in the plasma to the substrate is depressed can be realized

The process for alternately extracting negative ions and positive ions from pulse-time-modulated plasma of fluorine gas (F₂) may include a process of applying alternating current to the lower part electrode 28 as shown in FIG. 3. Specifically, in FIG. 3, to the upper part electrode 26, a direct current voltage of −50V is applied and to the power part electrode 28, an alternating current voltage of 100 V is applied and thereby negative ions and positive ions in pulse-time-modulated plasma of fluorine gas (F₂) are alternately accelerated and passed through the lower part electrode 28 with the result that a neutral beam 31 is generated.

The third process of the present invention is a plasma treatment process, which comprises the steps of feeding a treatment gas containing fluorine gas (F₂) to a plasma generating chamber, alternately repeating the application of a high frequency electric field and the stop of the application to generate a plasma, selectively extracting only negative ions from the plasma and neutralizing them to generate a neutral beam, and irradiating the neutral beam to the substrate and thereby carrying out substrate treatment, using, for example, a neutral beam generating apparatus as shown in FIG. 3.

As described above, the neutralization of negative ions proceeds by separation of electrons adhered on gas atoms and molecules so that a neutral beam can be generated with low energy and high efficiency as compared with neutralization of positive ions by electric charge exchange. In the case of extracting only negative ions and neutralizing them in this manner, the density of a neutral beam generated is lowered, while the proportion of neutralization of a neutral beam is increased. Therefore, charged particles remained in the neutral beam is decreased as compared with the process for extracting both of positive and negative ions and neutralizing them. As a result, anisotropic etching such that damage caused by irradiating charged particles and photon generated in plasma to a substrate is further depressed can be realized.

In the process for generating pulse-time-modulated plasma using a gas containing fluorine gas (F₂) as a treatment gas, the concentration of fluorine gas (F₂) contained in the treatment gas can be arbitrarily determined in accordance with the objects such as plasma treatment process or the like, and further in order to obtain high density plasma and a neutral beam with higher efficiency, it is preferred to use fluorine gas (F₂) having a higher concentration, and further, it is particularly preferred to use 100% by volume of fluorine gas (F₂).

As a treatment gas, chlorine gas (Cl₂), which is a gas having no greenhouse effect, similar to fluorine gas (F₂) is also preferably used in the kind of a gas for mixing with fluorine gas (F₂). In pulse-time-modulated plasma using the mixed gas of fluorine gas (F₂) and chlorine gas (Cl₂), changing the mixing ratio of fluorine gas (F₂) and chlorine gas (Cl₂), the mixing ratio of F (F⁻ ion and neutral F beam) and Cl (Cl⁻ ion and neutral Cl beam) can be easily changed, and plasma treatment or plasma etching treatment utilizing the difference of chemical properties or the difference of particle size between Fluorine (F) and chlorine (Cl) can be carried out.

For example, in etching of gate electrode poly-silicon, the etching reaction is proceeded rapidly by enhancing the fluorine gas (F₂) concentration in the initial etching step in which high rate etching is required, and process optimization utilizing the difference of the chemical properties of fluorine (F) and chlorine (Cl) can be performed by enhancing the concentration of chlorine gas (Cl₂) in the later etching step in which etching having high selectivity is required. Because the particles of fluorine (F) are smaller as compared with those of chlorine (Cl), it has a possibility of forming an etching process having low damage. It is preferred that the mixing ratio of fluorine gas and chlorine gas in the treatment gas be determined to an optimum ratio in accordance with the object for a plasma treatment process or plasma etching process.

As a feeding source of fluorine gas (F₂), it is possible to select and use any supplying system, for example, a fluorine gas cylinder filled with high pressure, a fluorine gas generating apparatus utilizing electrolysis reaction of hydrogen fluoride or thermal decomposition reaction of a metal fluoride or the like. Among the systems, the system utilizing thermal decomposition reaction of a solid metal fluoride is particularly preferred because the safety is higher and fluorine gas (F₂) having a higher purity can be supplied.

In generating a plasma using a treatment gas containing fluorine gas (F₂), the gas pressure in the plasma generating chamber, which can be optionally determined in accordance with the object for a plasma treatment method or the like, is from 0.1 to 100 Pa, preferably 0.3 to 10 Pa, particularly preferably 0.5 to 5 Pa. When the gas pressure is determined in the above range, high density plasma and a neutral beam can be prepared with high efficiency. When the gas pressure in the plasma generating chamber is lower than the above range, it is difficult to generate high density plasma, while when it is over the range, the generation efficiency of plasma and a neutral beam tends to be lowered.

In the process for generating the pulse-time-modulated plasma by alternately repeating the application (ON) of a high frequency electric field and the stop of the application (OFF) thereof to make a treatment gas into plasma, the combination of ON time and OFF time can be optionally determined, and it is general to employ a process of repeating the ON time and OFF time in several ten μsec order. In the case of using the gas containing fluorine gas (F₂) as a treatment gas according to the present invention, the OFF time is from 20 to 100 μsec, preferably 40 to 90 μsec, particularly preferably 50 to 70 μsec. When the OFF time is shorter than the above range, the generation of negative ions tends to be insufficient, while when it is over the above range, the electron density in the plasma is lowered to cause an effect such that discharging is difficult in the next ON time or an effect such that electron temperature is rapidly increased in the ON time, and thereby electrons are increased, with the result that the effect of pulse-time-modulation tends to be inhibited.

The plasma treatment process of the present invention as described above is preferably used to a process of fluorination treatment for precisely fluorinating the substrate surface (precisely control the depth of fluorine penetration into the substrate surface or gradient of fluorine concentration), a process of plasma etching for finely processing the surface of various substrates with low damage and high precision (anisotropy, selectivity, high rate) and other processes. The plasma treatment process, further, can be preferably used as a plasma etching technique of silicon and a silicon compound which technique is important in the production step of semiconductor devices or MEMS devices. Examples of the above silicon compound may include silicon oxide, silicon nitride, a silicate (such as glass-like sodium silicate, etc) or the like.

In particular, as compared with a process of using sulfur hexa-fluoride (SF₆), which process has been studied conventionally, the process of the present invention is very favorable as a fluorine (F⁻ ion and neutral F beam) source applicable to coming plasma etching techniques because favorable plasma and neutral beam for etching reaction can be generated.

Therefore, the present invention first enables forming the optimum process utilizing the difference of the chemical properties and particle size between fluorine (F) and chlorine (Cl) by the combined pulse-time-modulated plasma of chlorine gas (Cl₂) used as a chlorine (Cl⁻ ion and neutral Cl beam) source with the process of the present invention.

For example, in accordance with a substance to be etched and the etching object in each etching process, neutral F beam and neutral Cl beam are used properly or are mixed, so as to enhance the etching rate or the selectivity. Accordingly, the process of the present invention is sufficiently applicable to processes of etching new materials (Hf type high-k and all metal compounds containing noble metals) to be used in the coming new processes.

Therefore, utilizing the fine processing technique of the present invention, ultra high property-having semiconductor devices or new MEMS devices, which have not been produced until now, can be produced.

Moreover, because of using inexpensive fluorine gas (F₂) having no greenhouse effect as a treatment gas, the process of the present invention is harmonious with the environment and highly practical so that the technical value of the process is very high.

### EXAMPLES

Hereinafter, the present invention is described in more detail with reference to the following examples, but it should not be limited by these examples.

### Example 1

Using a plasma and neutral beam analysis apparatus as shown in FIG. 4, a continuous plasma, pulse-time-modulated plasma and neutral beam were generated from fluorine gas (F₂) and then the generated continuous plasma, pulse-time-modulated plasma and neutral beam were analyzed using QMS (quadrupole mass spectrometer), a microwave interferometer, an emission spectrometer, a Faraday cup and a calorimeter.

At first, the structure of the plasma and neutral beam analysis apparatus as shown in FIG. 4 is described below. In the plasma and neutral beam analysis apparatus as shown in FIG. 4, a quartz made plasma generating chamber 42 has the same structure as the quartz made plasma generating and substrate treatment chamber 2 in the pulse-time-modulated plasma generating apparatus as shown in FIG. 1. The plasma generating chamber 42 is provided with a port for feeding a treatment gas 41, and an antenna 43 for generating inductively coupled plasma is rolled up in a coil-like state to the outer periphery of the plasma generating chamber, and the antenna 43 is connected with a high frequency electric source 44 for generating plasma capable of pulse-time-modulation.

Plasma 45 (continuous plasma and pulse-time-modulated plasma) can be generated by, for example, applying RF bias having a discharge frequency of 13.56 MHz from the high frequency electric source 44 to the antenna 43.

Further, on the upper and lower parts inside the plasma generating chamber 42, a carbon-made upper part electrode 46 for accelerating ions and a carbon-made lower part electrode 48 for accelerating ions (electrode for extracting a beam) are provided and are connected to an electric source for voltage application (for upper part electrode) 47 and an electric source for voltage application (for lower part electrode) 49, respectively.

Utilizing the potential difference between the voltage of the upper part electrode 46 and the voltage of the lower part electrode 48, ions (positive or negative charged particles) generated in the plasma 45 is accelerated in a direction almost vertical to a measuring apparatus 52 disposed in a stainless steel made measuring chamber 50 and is irradiated almost vertically to the measuring apparatus 52.

In order to neutralize ions which are accelerated and extracted from the plasma 45, a plurality of pores (pore having a diameter of 1 mm and a depth of 10 mm) are provided in an area equivalent of 50% of the electrode area on the lower part electrode 48. The ion accelerated by the potential difference of the voltage applied on the upper part electrode 46 and the voltage applied on the lower part electrode 48 is neutralized by electric charge exchange, electron separation or the like during passing through the fine pores of the lower part electrode 48, to generate a neutral beam 51. The neutral beam 51 is irradiated in a direction almost vertical to the measuring apparatus 52.

The stainless steel measuring chamber 50 is exhausted by a turbo molecular pump for exhausting (not shown), and the exhaust gas 53 is subjected to non-toxicity treatment by an exhaust gas treating apparatus (not shown) to exhaust outside the system.

<Experiment 1>

Into the plasma generating chamber 42 in the plasma and neutral beam analysis apparatus as shown in FIG. 4, 30 ml/min of 100% by volume fluorine gas (F₂) was introduced as a treatment gas 41 and RF bias having a discharge frequency of 13.56 MHz (500 W or 1 kW) was continuously applied from the high frequency electric source 44 to the antenna 43, to generate a continuous plasma. In this time, the upper part electrode 46 and the lower part electrode 48 were in an earth connection state without application of a voltage. The pressure of the plasma generating chamber 42 was 1 Pa in the time of plasma generating. As the fluorine gas (F₂), fluorine gas (F₂) generated by K₃NiF₇ thermal decomposition reaction by heating a vessel filled with K₃NiF₇, which is a metal fluoride, at 350° C. is used.

In the measuring chamber 50, QMS (measuring apparatus 52) was provided so that a gas introducing port of the QMS was disposed at the position about 200 mm from the lower part in the lower part electrode 48, and measurement of the plasma 45 was carried out. In the case that the upper part electrode 46 and the lower part electrode 48 were in an earth connecting state without application of a voltage as described above, the plasma 45 generated in the plasma generating chamber 42 passed through the lower part electrode 48 while it kept the plasma composition and it was scarcely neutralized, and then was flown into the QMS. The measuring chamber 50 was rapidly exhausted by a turbo molecular pump for exhausting, the exhaust gas 53 was subjected to non-toxicity treatment by the exhaust gas treatment apparatus and exhausted outside the system.

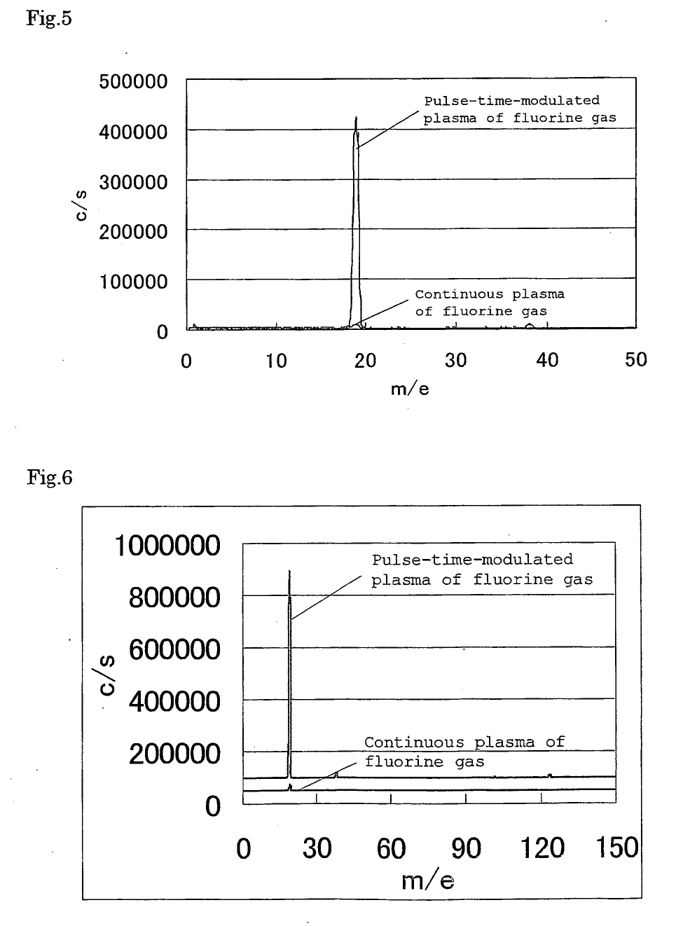

Through the above process, negative ions contained in the continuous plasma of fluorine gas (F₂) were analyzed with QMS measurement. The results of the analysis of RF bias=500 W is shown in FIG. 5 and the results of the analysis of RF bias=1 kW is shown in FIG. 6.

<Experiment 2>

The procedure of Experiment 1 in Example 1 was repeated except that into the plasma generating chamber 42 in the plasma and neutral beam analysis apparatus as shown in FIG. 4, 30 ml/min of 100% by volume fluorine gas (F₂) was introduced as a treatment gas 41 and RF bias having a discharge frequency of 13.56 MHz (2 kW during the ON time or 500 W during the ON time) was applied in a pulse-like state from the high frequency electric source 44 to the antenna 43, to generate a pulse-time-modulated plasma, the ON time/OFF time in pulse-time-modulation are 50 μsec/50 μsec and the voltage to be applied on the antenna 43 was modulated in a pulse-like state to generate a pulse-time-modulated plasma.

Through the above process, negative ions contained in the pulse-time-modulated plasma of fluorine gas (F₂) were analyzed with QMS measurement. The results of the analysis of RF bias=2 kW (during the ON time) are shown in FIG. 5 and the results of the analysis of RF bias=1 kW (during the ON time) are shown in FIG. 6.

As is clear from FIGS. 5 and 6, in the continuous plasma of fluorine gas (F₂), the amount of F⁻ ion generated was small, while in the pulse-time-modulated plasma of fluorine gas (F₂), the amount of F⁻ ion generated was remarkably increased.

<Experiment 3>

In the plasma generating chamber 42 of the plasma and neutral beam analysis apparatus as shown in FIG. 4, 30 mL/min of 100% by volume fluorine gas (F₂) was introduced as a treatment gas 41, RF bias having a discharge frequency of 13.56 MHz was continuously applied from the high frequency electric source 44 to the antenna 43 to generate a continuous plasma. In this time, the upper part electrode 46 and the lower part electrode 48 were in an earth connection state without application of a voltage. In the time of plasma generating, the pressure inside the plasma generating chamber 42 was 1 Pa. As the fluorine gas (F₂), fluorine gas (F₂) generated by K₃NiF₇ thermal decomposition reaction by heating a vessel filled with K₃NiF₇, which is a metal fluoride, at 350° C. is used.

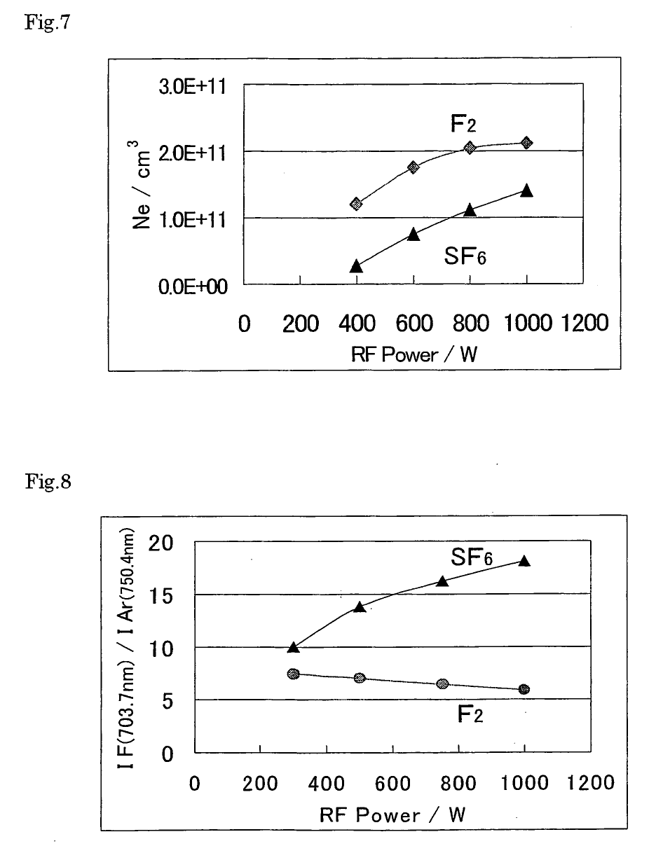

A microwave interferometer (not shown) was set outside the plasma generating chamber 42 and the electron density of the continuous plasma of fluorine gas (F₂) was measured. The output of a high frequency electric field for application to the antenna 43 was changed to generate a plasma, and with regard to the electron density of the continuous plasma of fluorine gas (F₂), the RF output dependency was measured. The analysis results are shown in FIG. 7.

FIG. 7 also shows the results of sulfur hexa-fluoride (SF₆) of Experiment 2 in Comparative Example 1 as described later for comparison. As is clear from FIG. 7, it was found that in the continuous plasma of fluorine gas (F₂), the electron density was higher as compared with sulfur hexa-fluoride (SF₆), and even in the case that the RF output was about 400 W, the electron density was not less than 1.0×10¹¹/cm³. Further, it was also found that the electron density increases monotonously in accordance with the increase of the RF output. The fact that the electron density of the continuous plasma is high shows that the electron density of the high frequency electric field in the pulse-time-modulated plasma during the ON time is high.

Therefore, as described above, it is expected that in the pulse-time-modulated plasma, electrons having a high density generated during the ON time were dissociatively adhered on fluorine gas (F₂) during the OFF time of the following high frequency electric field to generate a large amount of negative ion (F⁻).

<Experiment 4>

In the plasma generating chamber 42 of the plasma and neutral beam analysis apparatus as shown in FIG. 4, 30 mL/min of fluorine gas (F₂) and 1.5 mL/min of argon gas were introduced as a treatment gas 41, RF bias having a discharge frequency of 13.56 MHz was continuously applied from the high frequency electric source 44 to the antenna 43 to generate a continuous plasma. In this time, the upper part electrode 46 and the lower part electrode 48 were in an earth connection state without application of a voltage. In the time of plasma generating, the pressure inside the plasma generating chamber 42 was 1 Pa. As the fluorine gas (F₂), fluorine gas (F₂) generated by K₃NiF₇ thermal decomposition reaction by heating a vessel filled with K₃NiF₇, which is a metal fluoride, at 350° C. is used.

An emission spectrometer (not shown) was set outside the plasma generating chamber 42 and the emission spectrum of the continuous plasma of fluorine gas (F₂) was measured. The output of a high frequency electric field for application to the antenna 43 was changed to generate plasma, and with regard to the emission spectrum of the continuous plasma of fluorine gas (F₂), the RF output dependency was measured. From the emission spectrum obtained in each plasma condition, the intensity ratio of the emission peak (750.4 nm) of argon radical (Ar) to the emission peak (703.7 nm) of fluorine radical (F) [IF(703.7 nm)/IAr (750.4 nm)] was determined. It is possible to conduct relative comparison of the amount of fluorine radical (F) by the mutual comparison of IF(703.7 nm)/IAr (750.4 nm). The above method is an analysis procedure, which is generally called as emission actinometry. The analysis results are shown in FIG. 8.

FIG. 8 also shows the results of sulfur hexa-fluoride (SF₆) of Experiment 3 in Comparative Example 1 as described later for comparison. As is clear from FIG. 8, it was found that in the continuous plasma of fluorine gas (F₂), the value of IF(703.7 nm)/IAr (750.4 nm) was very low as compared with sulfur hexa-fluoride gas (SF₆), and even in the case of increasing the RF output to from 300 to 1000 W, the value of IF(703.7 nm)/IAr (750.4 nm) showed an almost definite value. That is, in the continuous plasma of fluorine gas (F₂), the fluorine (F) radical amount was very small in the RF output region where the measurement was carried out.

<Experiment 5>

The procedure of Experiment 2 in Example 1 was repeated except that in the plasma and neutral beam analysis apparatus as shown in FIG. 4, −100V of a direct current voltage was applied on the upper part electrode 46 and −50V of a direct current voltage was applied on the lower part electrode 48, to generate a pulse-time-modulated plasma of fluorine gas (F₂).

On the upper part electrode 46 and the lower part electrode 48, such potential difference was provided and thereby a large amount of negative ion (F⁻) generated inside the pulse-time-modulated plasma was accelerated in the direction almost vertical to the lower part electrode 48, and neutralized by separation of adhered electrons in the step of passing through the fine pores of the lower part electrode 48. As a result, a neutral beam 51 was generated and flown into the QMS (measuring apparatus 52) present in the measuring chamber 50.

By the above method, negative ions were selectively extracted from the pulse-time-modulated plasma of fluorine gas (F₂) and neutralized to generate a neutral beam. Negative ions remained in the generated neutral beam, namely un-neutralized negative ions were analyzed by the QMS measurement. The results are shown in FIG. 10. For the comparison, with regard to the pulse-time-modulated plasma of fluorine gas (F₂) in Experiment 2 of Example 1, the results of the negative ion analysis are also shown in FIG. 10.

As is clear from FIG. 10, in the neutral beam generated by selectively extracting negative ions from the pulse-time-modulated plasma of fluorine gas (F₂) and neutralizing them, un-neutralized negative ions (F⁻) remained were scarcely contained. That is, the results show that the neutralization rate of the neutral beam generated by selectively extracting negative ions from the pulse-time-modulated plasma of fluorine gas (F₂) and neutralizing them is very high, namely the neutralization has a high efficiency.

<Experiment 6>

The procedure of Experiment 5 in Example 1 was repeated except that as a measuring apparatus 52 set in the measuring chamber 50 as shown in FIG. 4, a Faraday cup (measuring apparatus 52) was used and set so that a gas introducing port of the Faraday cup was disposed at the position about 20 mm from the lower part in the lower part electrode 48, to generate a neutral beam by selectively extracting negative ions from the pulse-time-modulated plasma of fluorine gas (F₂) and neutralizing them. With regard to negative ions remained in the generated neutral beam, namely un-neutralized negative ions, the current density was measured using the Faraday cup. As a result, it was confirmed that the current density of negative ions remained in the neutral beam was less than the detectable lower limit (0.4 μA/cm²) and was very low.

From the results of measurement with the QMS and the Faraday cup, it was cleared that in the pulse-time-modulated plasma of fluorine gas (F₂), a large amount of F⁻ ions are generated, the F⁻ ions generated in a large amount in the plasma can be neutralized with high efficiency and the neutralization rate near to almost 100% is realized.

<Experiment 7>

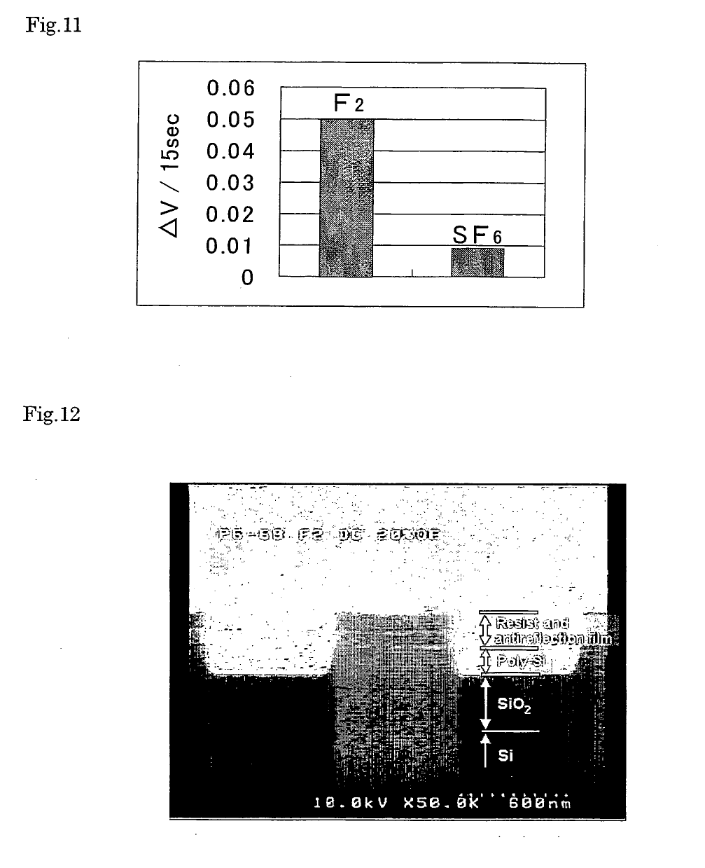

The procedure of Experiment 5 in Example 1 was repeated except that as the measuring apparatus 52 disposed in the measuring chamber 50 as shown in FIG. 4, a calorimeter was disposed, to generate a neutral beam by selectively extracting negative ions from a pulse-time-modulated plasma of fluorine gas (F₂) and neutralizing them. The flux of the resulting neutral beam was measured by the calorimeter. It is considered that the kinetic energy of the beam flown into the calorimeter is almost completely thermal exchanged in the calorimeter so that the change of the output voltage of the calorimeter (ΔV/15 sec) was taken as a flux of the neutral beam. The results are shown in FIG. 11.

In FIG. 11, the results of sulfur hexa-fluoride gas (SF₆) in Experiment 4 of Comparative Example 1 as described later for comparison are also shown. As is clear from FIG. 11, it was found that the flux of the neutral beam, which beam was generated by selectively extracting negative ions from the pulse-time-modulated plasma of fluorine gas (F₂) and neutralizing them, was five times or more as large as that of sulfur hexa-fluoride gas (SF₆).

### Example 2

Plasma etching for a substrate was carried out by a pulse-time-modulated plasma of fluorine gas (F₂), the etching rate of silicon (Si) was measured and the etching form was observed.

<Experiment 1>

Using a pulse-time-modulated plasma generating apparatus as shown in FIG. 2, 30 mL/min of the 100% by volume fluorine gas (F₂) same as one used in Example 1 was introduced as a treatment gas 61 into a plasma generating and substrate treatment chamber 62, and RF bias (1 kW) having a discharge frequency of 13.56 MHz was applied from a high frequency electric source 64 to an antenna 63 to generate a continuous plasma 65.

To a carbon made electrode for accelerating ion 68, RF bias of 1 MHz was applied with an output of 50 W from an electric source for applying voltage 69. By applying the RF bias to the carbon made electrode for accelerating ion 68 in this manner, positive and negative ions generated in the plasma 65 were accelerated in the direction almost vertical to a substrate holding base 70 and irradiated on the substrate.

The substrate holding base 70 was disposed at the position 50 mm from the lower part of the plasma generating part and cooled to −20° C. On the substrate holding base 70, a silicon (Si) substrate that an aluminum thin film was deposited on the surface thereof as an etching mask was disposed and the substrate was subjected to plasma etching by the plasma 65. The etching rate was determined in the following manner. Etching treatment was carried out several times by changing only the etching treatment time and then the etching depth was measured using a step measuring apparatus. The etching rate obtained in the experiment is shown in Table 1.

<Experiment 2>

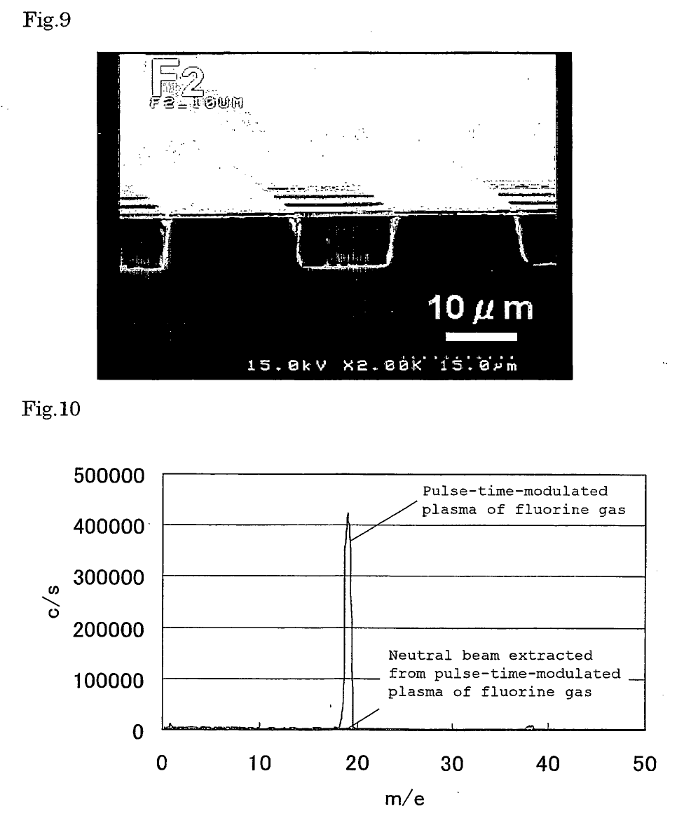

The procedure of Experiment 1 in Example 2 was repeated except that RF bias of 1 kW having a discharge frequency of 13.56 MHz (during the ON time) was applied in a pulse state from the high frequency electric source 64 to the antenna 63, to generate pulse-time-modulated plasma 65, and thereby plasma etching for the substrate was carried out. In this procedure, the ON time/OFF time in the pulse-time-modulation were 50 μsec/50 μsec. The etching rate obtained in the experiment is shown in Table 1. FIG. 9 shows an image of the etching form observed by SEM (scanning electron microscope).

TABLE 1

| | Si etching rate |
|---|---|
| | (nm/min) |
| Experiment 1 Continuous plasma | 840 |
| Experiment 2 Pulse-time-modulated plasma | 1220 |

As is clear from Table 1, it was found that the etching rate of the pulse-time-modulated plasma of fluorine gas (F₂) (RF output=1 kW (during the ON time) was about 1.5 times higher than the etching rate of the continuous plasma of fluorine gas (F₂) (RF output=1 kW) even though the substantial plasma power thereof was half (0.5 time) of that of the continuous plasma of fluorine gas (F₂). Furthermore, from FIG. 9, it was substantiated that the Si etching can proceed vertically without the formation of a sidewall protecting film. Moreover, from these results, it is also revealed that a large amount of negative ions (F⁻) generated in the plasma by pulse modulating the plasma of fluorine gas (F₂) greatly contributes to Si etching. In the etching with the pulse-time-modulated plasma of fluorine gas (F₂), while favorable vertical processing is kept, the etching rate is over 1 μm/min. These results satisfy the processing conditions which are required in the production processes of MEMS and the like.

### Example 3

From pulse-time-modulated plasma of fluorine gas (F₂), negative ions were selectively extracted and neutralized to generate a neutral beam. By the neutral beam, plasma etching of a substrate was carried out. In order to examine the composition of the neutral beam, etching rates of polysilicon (Poly-Si) and SiO₂ were measured using electrodes of extracting beams having a different F radical-adhering coefficient, and further the etching form of Poly-Si was observed.

<Experiment 1>

Using the neutral beam generating apparatus as shown in FIG. 3, 30 mL/min of the 100% by volume fluorine gas (F₂) same as that used in Example 1 was introduced as a treatment gas 21 to a plasma generating chamber 22, and RF bias of 1 kW having a discharge frequency of 13.56 MHz (during the ON time) was applied in a pulse state from a high frequency electric source 24 to an antenna 23, to generate pulse-time-modulated plasma. In this procedure, the ON time/OFF time in the pulse-time-modulation were 50 μsec/50 μsec.

To the upper part electrode 26, a direct current voltage of −100V was applied and to the power part electrode 28, a direct current voltage of −50 V was applied. By providing such potential difference, negative ions (F⁻) generated in the pulse-time-modulated plasma was accelerated in the direction almost vertical to the lower part electrode 28, neutralized by separation of adhered electrons in the step of passing through fine pores of the lower part electrode 28 to generate a neutral beam 31 and the neutral beam were flown into a stainless steel made substrate treatment chamber 30.

A substrate holding base 32 of the substrate treatment chamber 30 was disposed at the position 20 mm from the lower part of the lower part electrode 28 and cooled to −20° C. A substrate having a Poly-Si film or SiO₂ film on its surface was disposed on the substrate holding base 32 and plasma etching thereof was carried out by the above neutral beam 31. The etching rates of Poly-Si and SiO₂ were determined in the following manner. Etching treatment was carried out several times by changing only the etching treatment time and then the etching depth was measured using a step measuring apparatus.

Next, the etching rates of Poly-Si and SiO₂ were measured in the above conditions except for using an electrode for extracting beam in which the surface of the lower part electrode 28 was coated by spraying alumina. These measurement results are inclusively shown in Table 2.

TABLE 2

Etching rate (nm/min)

| | Poly-Si | SiO₂ |
|---|---|---|
| Carbon made electrode | 9.5 | 1.42 |
| Alumina sprayed electrode | 20.2 | 5.24 |

Spraying alumina on the carbon electrode surface, the adhesion of F radical on the surface of the electrode for extracting beam and the reaction thereof can be depressed. Therefore, when the alumina sprayed electrode is used as an electrode for extracting beam, F radicals present in the plasma are hardly disappeared by the reaction with the electrode and thereby, as they are, mingle into the neutral beam.

Accordingly, in the case of using the carbon made electrode and in the case of using the alumina sprayed electrode, the proportion that F radicals contribute to the etching properties for a substrate can be presumed by measuring the etching rate. Namely, in the case that a large amount of radicals are present in the neutral beam, it is considered that the etching rate in the case of using the alumina sprayed electrode in which the disappearance of radicals is depressed is remarkably larger than the etching rate in the case of using the carbon electrode in which radicals are disappeared.

Furthermore, it is considered that although the Poly-Si is spontaneously etched not only by neutral F beam but also by diffusing F radicals, the SiO₂ etching is performed by a large contribution of neutral beam having large kinetic energy. Therefore, measuring the etching rates both of the Poly-Si and SiO₂, the proportion of F radicals mingled into the neutral F beam can be presumed. Namely, in the case that a large amount of radicals are present in the neutral beam, the etching rate of the Poly-Si is larger, while the etching rate of the SiO₂ is smaller.

As is clear from Table 2, in the neutral beam generated by selectively extracting negative ions from the pulse-time-modulated plasma of fluorine gas (F₂) and neutralizing them, when the case of using a carbon made electrode as an electrode for extracting beam with the case of using an alumina sprayed electrode are compared, it was found that with regard to the etching rate of the Poly-Si, the difference there between was not large. Namely, it is revealed that in the neutral beam generated by selectively extracting negative ions from the pulse-time-modulated plasma of fluorine gas (F₂) and neutralizing them, the amount of F radicals not having directionality generated is small. Simultaneously, this result shows that not only in the neutralized neutral beam but also in the pulse-time-modulated plasma of fluorine gas (F₂) per se, the amount of F radicals generated is small.

<Experiment 2>

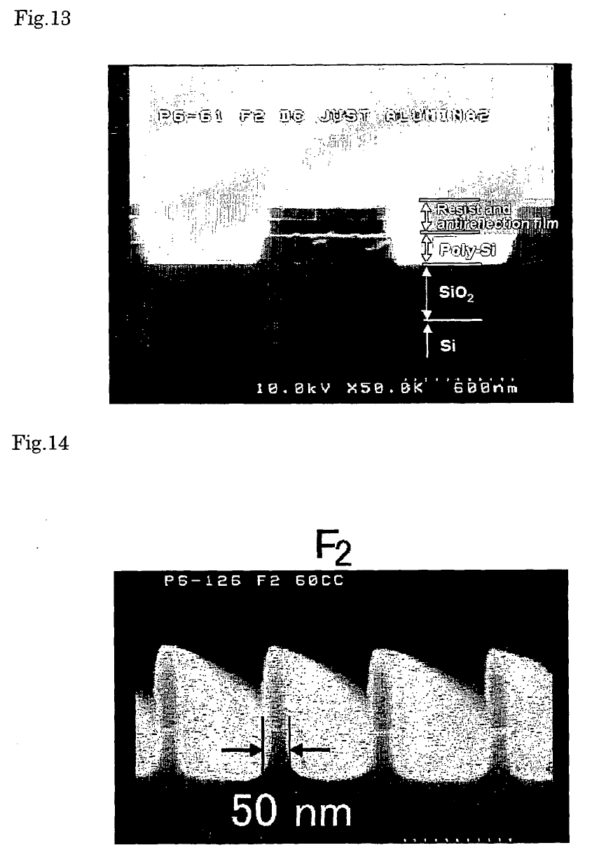

Using the neutral beam generating apparatus as shown in FIG. 3, the Poly-Si was etched by the same process as in Experiment 1 of Example 3 and the etching form was evaluated by observation with SEM (scanning electron microscope). The sample used for etching form evaluation was prepared by forming a SiO₂ film (300 nm) on a Si substrate by thermal oxidation treatment and depositing thereon a polysilicon (Poly-Si) film having a thickness of 150 nm. As an etching mask, on the Poly-Si surface, an antireflection film and a resist were applied and subjected to exposure and development treatment. In order to evaluate the etching form, the etching treatment time was determined to the condition such that the etching is carried out too much by 20%, that is, the etching treatment time is determined to the time capable of etching the Poly-Si film thickness of 180 nm which is 1.2 times as much as the thickness of 150 nm of the Poly-Si film. With regard to the case of using the carbon electrode and the case of using the alumina sprayed electrode as the electrode of extracting beam, the results are shown in FIG. 12 and FIG. 13 respectively.

As is clear from the SEM observation results as shown in FIG. 12 and FIG. 13, in the neutral beam generated by selectively extracting negative ions from the pulse-time-modulated plasma of fluorine gas (F₂) and neutralizing them, anisotropic etching with high accuracy was realized and it verifies the supposition that in the neutral beam, the amount of F radicals generated is small, disclosed in the results of Experiment 1 in Example 3.

### Example 4

By the neutral beam generated by selectively extracting negative ions from the pulse-time-modulated plasma of fluorine gas (F₂) and neutralizing them, plasma etching for a substrate was carried out. The substrate used herein was prepared by depositing a polysilicon (Poly-Si) film having a gate length of 50 nm which length is desired in the coming etching.

The procedure of Experiment 1 in Example 3 was repeated except that the neutral beam generating apparatus as shown in FIG. 3 was used and the lower part electrode 28 was in a earth connection state and thereby a Poly-Si film was etched. The etching rate and the etching form were evaluated by observation with SEM (scanning electron microscope). The electrode of extracting beam 28 was a carbon electrode. The results are shown in FIG. 14.

As is clear from FIG. 14, by the neutral beam generated by selectively extracting negative ions from the pulse-time-modulated plasma of fluorine gas (F₂) and neutralizing them, the formation of a Polysilicon (Poly-Si) pattern having a width of 50 nm was accomplished. Further, the etching rate was 29.4 nm/min so that the practical rate could be attained in processing gate electrodes.

### Comparative Example 1

Pulse-time-modulated plasma was generated using a sulfur hexa-fluoride gas (SF₆) as a treatment gas and a neutral beam extracted from the pulse-time-modulated plasma was generated, and then the analyses thereof were carried out by various measuring apparatuses. The comparison with Example 1 as described was carried out and it was confirmed that the case of using fluorine gas (F₂) as a treatment gas was superior.

<Experiment 1>

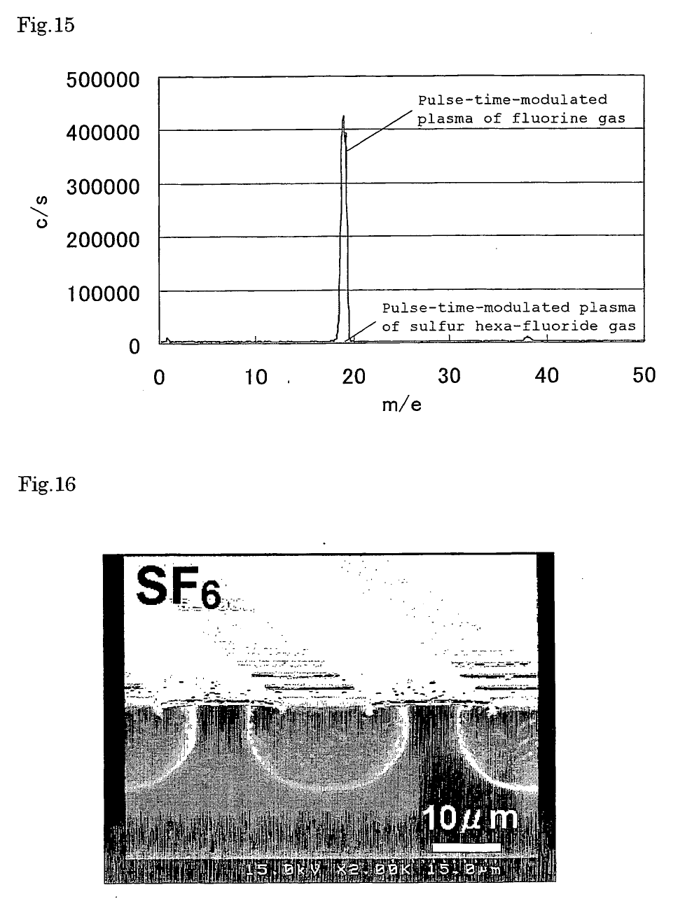

The procedure of Experiment 2 in Example 1 was repeated except for using a sulfur hexa-fluoride gas (SF₆) as a treatment gas and negative ions in the pulse-time-modulated plasma of sulfur hexa-fluoride gas (SF₆) were analyzed by QMS measurement. The analysis results are shown in FIG. 15. For comparison, FIG. 15 also shows the analysis results of the negative ions in the pulse-time-modulated plasma of fluorine gas (F₂) in Experiment 2 of Example 1.

As is clear from FIG. 15, in the pulse-time-modulated plasma of sulfur hexa-fluoride gas (SF₆), F⁻ ions were scarcely generated and the amount of F⁻ ions was remarkably smaller as compared with the pulse-time-modulated plasma of fluorine gas (F₂)

<Experiment 2>

The procedure of Experiment 3 in Example 1 was repeated except for using sulfur hexa-fluoride gas (SF₆) as a treatment gas and the electron density of continuous plasma of sulfur hexa-fluoride gas (SF₆) was measured. The analysis results are shown in FIG. 7.

FIG. 7 also shows the results of fluorine gas (F₂) in Experiment 3 of Example 1 as described for comparison. From FIG. 7, it was confirmed that the continuous plasma of fluorine gas (F₂) has a larger electron density as compared with that of sulfur hexa-fluoride gas (SF₆), namely, the ionization efficient of fluorine gas (F₂) is higher than that of sulfur hexa-fluoride gas (SF₆).

<Experiment 3>

The procedure of Experiment 4 in Example 1 was repeated except for using, as a treatment gas, 30 mL/min of sulfur hexa-fluoride gas (SF₆) and 1.5 mL/min of argon gas and the amount of fluorine radical (F) of continuous plasma of sulfur hexa-fluoride gas (SF₆) was measured. The analysis results are shown in FIG. 8.

FIG. 8 also shows the results of fluorine gas (F₂) in Experiment 4 of Example 1 as described for comparison. From FIG. 8 it was confirmed that the continuous plasma of fluorine gas (F₂) has a very smaller value of the rate of IF (703.7 nm)/IAr (750.4 nm) as compared with that of sulfur hexa-fluoride gas (SF₆), namely, the continuous plasma of fluorine gas (F₂) has a low content of fluorine (F) radical.

<Experiment 4>

The procedure of Experiment 7 in Example 1 was repeated except for using sulfur hexa-fluoride gas (SF₆) as a treatment gas and then with regard to the resulting the neutral beam generated by selectively extracting negative ions from the pulse-time-modulated plasma of sulfur hexa-fluoride gas (SF₆) and neutralizing them, the flux was measured. The results are shown in FIG. 11.

FIG. 11 also shows the results of fluorine gas (F₂) in Experiment 7 of Comparative Example 1 as described for comparison. As is clear from FIG. 11, it was confirmed that the neutral beam generated by selectively extracting negative ions from the pulse-time-modulated plasma of fluorine gas (F₂) and neutralizing them, has a flux 5 times or more as large as that of sulfur hexa-fluoride gas (SF₆).

### Comparative Example 2

Using pulse-time-modulated plasma generated using a sulfur hexa-fluoride gas (SF₆) as a treatment gas, plasma etching for a substrate was carried out, and then the etching rate of a silicon (Si) substrate was measured and the etching form was observed. In comparison with Example 2 as described above, it was confirmed that the case of using fluorine gas (F₂) as a treatment gas was superior.

<Experiment 1>

The procedure of Experiment 2 in Example 1 was repeated except for using a sulfur hexa-fluoride gas (SF₆) as a treatment gas and thereby continuous plasma of sulfur hexa-fluoride gas (SF₆) was generated and plasma etching for a silicon (Si) substrate was carried out. The etching rate was determined in the following manner. Etching treatment was carried out several times by changing only the etching treatment time and then the etching depth was measured using a step measuring apparatus. The etching rate obtained in the experiment is shown in Table 3.

<Experiment 2>

The procedure of Experiment 2 in Example 2 was repeated except for using sulfur hexa-fluoride gas (SF₆) as a treatment gas and thereby, etching for a silicon (Si) substrate was carried out by the pulse-time-modulated plasma. The etching rate obtained in the experiment is shown in Table 3. Furthermore, the image of the etching form observed by SEM (scanning electron microscope) is shown in FIG. 16.

TABLE 3

| | Si etching rate |
|---|---|
| | (nm/min) |
| Experiment 1 Continuous plasma | 4760 |
| Experiment 2 Pulse-time-modulated plasma | 3590 |

As is clear from Table 3, it was found that as compared with the etching rate with the continuous plasma (RF output=1 kW) of sulfur hexa-fluoride gas (SF₆), the etching rate of the pulse-time-modulated plasma (RF output=1 kW during the ON time) is smaller. This fact is largely different from the results of Experiments 1 and 2 in Example 2 (Table 1) as described above. The fact that the etching rate of the pulse-time-modulated plasma of sulfur hexa-fluoride gas (SF₆) is smaller than the etching rate of the continuous plasma is considered due to such reasons that one reaction species mainly contributing to the etching reaction of the sulfur hexa-fluoride gas (SF₆) plasma is radical and in the pulse-time-modulated plasma, the amount of the radical generated is smaller as compared with that in the continuous plasma. Furthermore, from FIG. 16, it was also confirmed that in the pulse-time-modulated plasma of sulfur hexa-fluoride gas (SF₆), large undercuts (side etching) were caused in the Si etching, namely, isotropic etching proceeded.

### Comparative Example 3

### Experiment 1

The procedure of Experiment 1 in Example 3 was repeated except for using sulfur hexa-fluoride gas (SF₆) as a treatment gas and thereby pulse-time-modulated plasma of sulfur hexa-fluoride gas (SF₆) was generated and neutral beam was generated by selectively extracting negative ions from the pulse-time-modulated plasma and neutralizing them. The etching rates for polysilicon (Poly-Si) and SiO₂ were measured using the neutral beam. The results are shown in Table 4.

TABLE 4

Etching rate (nm/min)

| | Poly-Si | SiO₂ |
|---|---|---|
| Carbon made electrode | 49.2 | 0.74 |
| Alumina sprayed electrode | 1356 | 3.7 |

As is clear from Table 4, with regard to the neutral beam generated by selectively extracting negative ions from the pulse-time-modulated plasma of sulfur hexa-fluoride (SF₆) and neutralizing them, when the case of using the carbon made electrode as an electrode for extracting beam was compared with the case of using the alumina sprayed electrode as an electrode for extracting beam, it was found that the difference of the etching rate for Poly-Si was very large. Namely, this result shows that in conventional pulse-time-modulated plasma of sulfur hexa-fluoride (SF₆), the amount of F radical generated in the plasma is very large as compared with the pulse-time-modulated plasma of fluorine (F₂).

Furthermore, when Table 2 is compared with Table 4, with regard to the etching rate for SiO₂, which is considered to have a large contribution by neutral F beam having large kinetic energy, the etching rate in the case of using fluorine gas (F₂) is higher than the etching rate in the case of using sulfur hexa-fluoride gas (SF₆) even in any of the case of using the carbon made electrode and the case of using the alumina sprayed electrode. This results shows that the pulse-time-modulated plasma of fluorine gas (F₂) has a remarkably excellent efficiency of generating neutral F beam as compared with the conventional pulse-time-modulated plasma of sulfur hexa-fluoride gas (SF₆).

### Experiment 2

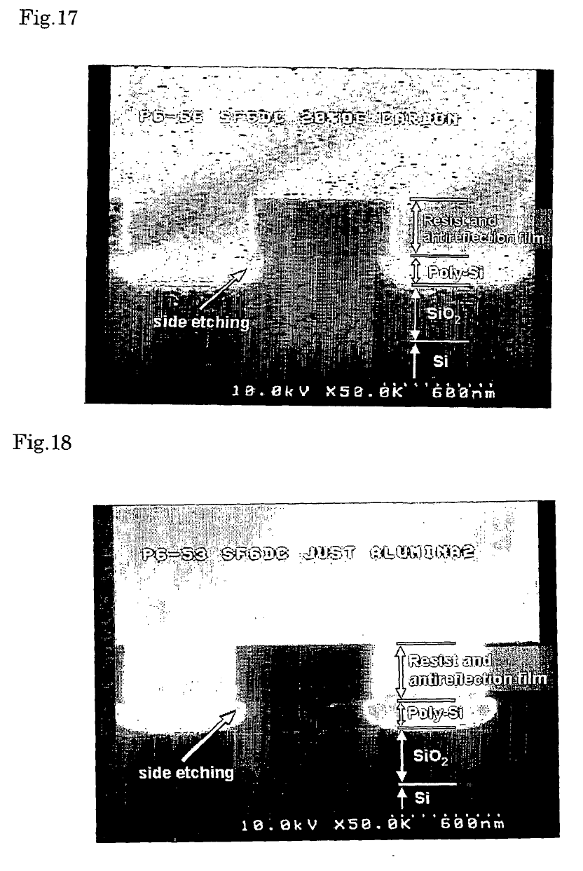

The procedure of Experiment 2 in Example 3 was repeated except for using sulfur hexa-fluoride gas (SF₆) as a treatment gas and thereby Poly-Si was etched and the etching form was evaluated by observation with SEM (scanning electron microscope). The results in the case of using the carbon electrode as an electrode for extracting beam are shown in FIG. 17 and the results in the case of using the alumina sprayed electrode are shown in FIG. 18.

In the SEM image as shown in FIGS. 17 and 18, clear side etching was observed under the etching mask. Such side etching shows that the amount of radicals (F atom not having directionality) mingled into the neutral beam is large. Particularly, in the case of using the alumina sprayed electrode, side etching remarkably appeared. This result shows that the radical amount is large as compared with the case of using the carbon electrode.

Therefore, in the neutral beam generated by selectively extracting negative ions from the pulse-time-modulated plasma of sulfur hexa-fluoride (SF₆) and neutralizing them, the etching form was isotropic and it was revealed that anisotropic etching cannot be attained. That is, this fact supports the effect in Experiment 1 of Comparative Example 3 such that in the neutral beam using sulfur hexa-fluoride (SF₆), the amount of F radical not having directionality generated was remarkably large.

From the experiment results, when the pulse-time-modulated plasma using fluorine gas (F₂) as a treatment gas was compared with conventional pulse-time-modulated plasma using sulfur hexa-fluoride gas (SF₆), it was revealed that the amount of F⁻ ion generated is remarkably large while the amount of generated F radical not having polarity, which will cause disturbance in fine processing, is remarkably small. Furthermore, it was revealed that the neutral beam extracted from the pulse-time-modulated plasma using fluorine gas (F₂) as a treatment gas is neutral F beam having uniform directionality, and the anisotropic etching can be realized. the three requirements for processing technique including the article (1) such that the etching can attain a high etching rate, the article (2) such that the verticality of an etching profile can be attained and the article (3) such that the etched wall surface has excellent smoothness.

### DISCLOSURE OF INVENTION

It is an object of the invention to develop a plasma processing process using a gas having no greenhouse effect and to provide a plasma etching process with high accuracy capable of depressing damage to devices, in order to realize the global environmental preservation and the advancement of plasma process performance.

The present inventor have been earnestly studied to solve the above problems and succeeded in developing the process for plasma processing process with high accuracy utilizing a gas having no greenhouse effect for the first time.

The present invention relates the following items.

(1) A process for plasma treatment comprises the steps of feeding a treatment gas containing a fluorine gas (F₂) into a plasma generating chamber, alternately repeating application of a high frequency electric field and stop of the application thereof to generate plasma, and carrying out substrate treatment by irradiating the plasma to a substrate.

(2) A process for plasma treatment comprises the steps of feeding a treatment gas containing a fluorine gas (F₂) into a plasma generating chamber, alternately repeating application of a high frequency electric field and stop of the application thereof to generate plasma, individually or alternately extracting negative ions or positive ions from the plasma and neutralizing them to generate a neutral beam, and carrying out substrate treatment by irradiating the neutral beam to a substrate.

(3) A process for plasma treatment comprises the steps of feeding a treatment gas containing a fluorine gas (F₂) into a plasma generating chamber, alternately repeating application of a high frequency electric field and stop of the application thereof to generate plasma, selectively extracting only negative ions from the plasma and neutralizing them to generate a neutral beam, and carrying out substrate treatment by irradiating the neutral beam to a substrate.

(4) The process for plasma treatment according to any one of the items (1) to (3), wherein the treatment gas is 100% by volume of fluorine gas (F₂).

(5) The process for plasma treatment according to any one of the items (1) to (3), wherein the treatment gas is a mixed gas of fluorine gas (F₂) and chlorine gas (Cl₂).

(6) The process for plasma treatment according to any one of the items (1) to (5), wherein the fluorine gas (F₂) is fluorine gas (F₂) generated by thermally decomposing a solid metal fluoride.

(7) The process for plasma treatment according to any one of the items (1) to (6), wherein in the generating the plasma, the gas pressure of a plasma generating chamber is from 0.1 to 100 Pa.

(8) The process for plasma treatment according to any one of the items (1) to (7), wherein in the generating the plasma, the stop time of the application of high frequency electric field is from 20 to 100 μsec.

(9) A process for fluorination treatment which process is characterized by utilizing the process for plasma treatment as described in any one of the items (1) to (8).

(10) A process for plasma etching a substrate which process is characterized by utilizing the process for plasma treatment as described in any one of the items (1) to (8).

(11) A process for plasma etching silicon or a silicon compound which process is characterized by utilizing the process for plasma etching as described in the item (10).

(12) The process for plasma etching according to the item (11) wherein the silicon compound comprises silicon oxide, silicon nitride or a silicate.

(13) The semiconductor device produced by the process as described in any one of the items (1) to (12).

(14) The micro machine (MEMS: Micro Electric Mechanical System) device produced by the process as described in any one of the items (1) to (12).

### EFFECT OF THE INVENTION

Using the plasma treatment process by use of a gas having no greenhouse effect according to the present invention, the plasma etching treatment with high accuracy suitable for fine processing in production of semiconductor devices can be attained. Particularly, from plasma, only neutral beams necessary for etching reaction are taken out and are irradiated on a substrate and thereby the production process for coming generation semiconductor devices in which processing patterns are finned into a size of not more than 0.1 μm can be realized. Furthermore, the production process is effective as a fine processing technique in the production of MEMS devices and the like which have recently been developed.

### BRIEF DESCRIPTION OF DRAWINGS

FIG. 1 is a schematic view (example 1) showing one embodiment of a pulse-time-modulated plasma generating apparatus capable of carrying out the plasma treatment process and the plasma etching process according to the present invention.

FIG. 2 is a schematic view (example 2) showing one embodiment of a pulse-time-modulated plasma generating apparatus capable of carrying out the plasma treatment process and the plasma etching process according to the present invention.

FIG. 3 is a schematic view showing one embodiment of a neutral beam generating apparatus capable of carrying out the plasma treatment process and the plasma etching process according to the present invention.

FIG. 4 is a schematic view showing a plasma and neutral beam analysis apparatus used in experiments of Example 1 and Comparative Example 1.

FIG. 5 is a QMS spectrum of negative ions in continuous plasma [RF bias=500 W] and pulse-time-modulated plasma [RF bias=2 kW (during the ON time)] in the case of using fluorine gas (F₂) as a treatment gas according to Example 1.

FIG. 6 is a QMS spectrum of negative ions in continuous plasma [RF bias=1 kW] and pulse-time-modulated plasma [RF bias=1 kW (during the ON time)] in the case of using fluorine gas (F₂) as a treatment gas according to Example 1.

FIG. 7 is a result of measuring an electron density in continuous plasma in each of the case of using fluorine gas (F₂) and the case of using sulfur hexa-fluoride gas (SF₆) as a treatment gas according to Example 1 and Comparative Example 1.

FIG. 8 is a result of measuring an F radical amount in continuous plasma in each of the case of using fluorine gas (F₂) and the case of using sulfur hexa-fluoride gas (SF₆) as a treatment gas according to Example 1 and Comparative Example 1.

FIG. 9 is an image observed with SEM concerning to a substrate (silicon surface provided with aluminum pattern) etched by pulse-time-modulated plasma generated using fluorine gas (F₂) as a treatment gas according to Example 2.

FIG. 10 shows QMS spectrums of negative ion in pulse-time-modulated plasma generated using fluorine gas (F₂) as a treatment gas and residual negative ion in neutral beam generated by selectively extracting negative ion from the plasma according to Example 1.

FIG. 11 is a result of measuring the total flux of neutral beam generated by selectively extracting negative ion from pulse-time-modulated plasma in each of the case of using fluorine gas (F₂) and the case of using sulfur hexa-fluoride gas (SF₆) as a treatment gas according to Example 1 and Comparative Example 1.

FIG. 12 is an image observed with SEM concerning to a substrate (polysilicon surface provided with resist pattern) etched by neutral beam in the case of selectively extracting negative ions with the use of the carbon made electrode for extracting beam from pulse-time-modulated plasma generated using fluorine gas (F₂) as a treatment gas according to Example 3.

FIG. 13 is an image observed with SEM concerning to a substrate (polysilicon surface provided with resist pattern) etched by neutral beam in the case of selectively extracting negative ions with the use of the carbon made electrode having an alumina sprayed surface for extracting beam from pulse-time-modulated plasma generated using fluorine gas (F₂) as a treatment gas according to Example 3.

FIG. 14 is an image observed with SEM concerning to a substrate (polysilicon surface provided with resist pattern having a line width of 50 nm) etched by neutral beam generated by selectively extracting negative ions from pulse-time-modulated plasma generated using fluorine gas (F₂) as a treatment gas according to Example 4.

FIG. 15 is a QMS spectrum of negative ions in pulse-time-modulated plasma in each of the case of using fluorine gas (F₂) and the case of using sulfur hexa-fluoride gas (SF₆) as a treatment gas according to Example 1 and Comparative Example 1.

FIG. 16 is an image observed with SEM concerning to a substrate (silicon surface provided with aluminum pattern) etched by pulse-time-modulated plasma generated using sulfur hexa-fluoride gas (SF₆) as a treatment gas according to Comparative Example 2.

FIG. 17 is an image observed with SEM concerning to a substrate (polysilicon surface provided with resist pattern) etched by neutral beam in the case of selectively extracting negative ions with the use of the carbon made electrode for extracting beam from pulse-time-modulated plasma generated using sulfur hexa-fluoride gas (SF₆) as a treatment gas according to Comparative Example 3.

FIG. 18 is an image observed with SEM concerning to a substrate (polysilicon surface provided with resist pattern) etched by neutral beam in the case of selectively extracting negative ions with the use of the carbon made electrode having an alumina sprayed surface for extracting beam from pulse-time-modulated plasma generated using sulfur hexa-fluoride gas (SF₆) as a treatment gas according to Comparative Example 3.

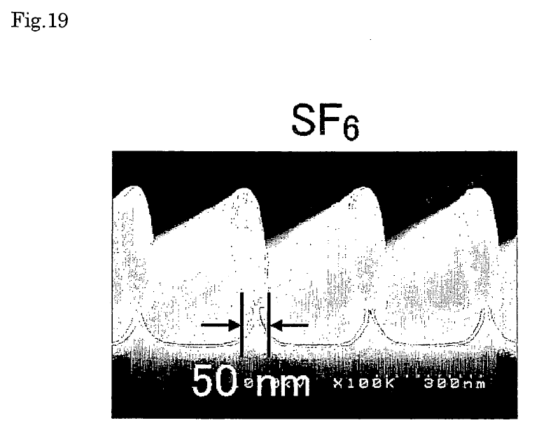

FIG. 19 is an image observed with SEM concerning to a substrate (polysilicon surface provided with resist pattern having a line width of 50 nm) etched by neutral beam generated by selectively extracting negative ions from pulse-time-modulated plasma generated using sulfur hexa-fluoride gas (SF₆) as a treatment gas according to Comparative Example 4.

### DESCRIPTION OF REFERENCE NUMERALS

1 Treatment gas
2 Quartz made plasma generating and substrate treatment chamber
3 Antenna for generating inductively coupled plasma
4 High frequency electric source for generating plasma capable of pulse-time-modulation
5 Plasma
6 Carbon made upper part electrode for accelerating ion
7 Electric source for voltage application (for upper part electrode)
8 Carbon made lower part electrode for accelerating ion
9 Electric source for voltage application (for lower part electrode)
10 Substrate holding base
11 Substrate
12 Exhaust gas
21 Treatment gas
22 Quartz made plasma-generating chamber
23 Antenna for generating inductively coupled plasma
24 High frequency electric source for generating plasma capable of pulse-time-modulation
25 Plasma
26 Carbon made upper part electrode for accelerating ion
27 Electric source for voltage application (for upper part electrode)
28 Carbon made lower part electrode for accelerating ion (electrode for extracting beam)
29 Electric source for voltage application (for lower part electrode)
30 Stainless steel made substrate treatment chamber
31 Neutral beam
32 Substrate holding base
33 Substrate
34 Exhaust gas
41 Treatment gas
42 Quartz made plasma-generating chamber
43 Antenna for generating inductively coupled plasma
44 High frequency electric source for generating plasma capable of pulse-time-modulation
45 Plasma
46 Carbon made upper part electrode for accelerating ion
47 Electric source for voltage application (for upper part electrode)
48 Carbon made lower part electrode for accelerating ion (electrode for extracting beam)
49 Electric source for voltage application (for lower part electrode)
50 Stainless steel measuring chamber
51 Neutral beam
52 Measuring apparatus
53 Exhaust gas
61 Treatment gas
62 Plasma generating and substrate treatment chamber
63 Antenna for generating inductively coupled plasma
64 High frequency electric source for generating plasma capable of pulse-time-modulation
65 Plasma
68 Carbon made electrode for accelerating ion
69 Electric source for voltage application
70 Substrate holding base
71 Substrate
72 Exhaust gas

### BEST MODE FOR CARRYING OUT THE INVENTION

The process for plasma treatment and the plasma etching process using the treatment process according to the present invention will be described in detail hereinafter.

One example of a pulse-time-modulated plasma generating apparatus capable of carrying out the plasma treatment process and the plasma etching process according to the present invention is shown in FIG. 1. The structure of the pulse-time-modulated plasma generating apparatus as shown in FIG. 1 is described below.

In the pulse-time-modulated plasma generating apparatus as shown in FIG. 1, an antenna 3 for generating inductively coupled plasma is rolled up in a coil-like state into the outer periphery of a plasma generating and substrate treatment chamber 2 made of quartz provided with a port for feeding a treatment gas 1, and the antenna 3 is connected with a high frequency electric source 4 for generating plasma capable of pulse-time-modulation.

Applying a high frequency electric field from the outside of the plasma generating and substrate treatment chamber 2 in which the treatment gas 1 has been fed, plasma 5 is generated in the plasma generating and substrate treatment chamber 2. Continuously applying a high frequency electric field generates usual plasma (hereinafter referred to continuous plasma), and alternately repeating the application of a high frequency electric field and the stop of the application can generate pulse-time-modulated plasma. The application of a high frequency electric field and the stop of the application can be carried out by, for example, applying RF bias having a discharge frequency of 13.56 MHz in a pulse state from the high frequency electric source 4 to the antenna 3. The alternate repeating time (pulse width) of the application of a high frequency electric field and the stop of the application can be arbitrarily determined.

Further, on the upper and lower parts inside the plasma generating and substrate treatment chamber 2, a carbon-made upper part electrode 6 for accelerating ions and a carbon-made lower part electrode 8 for accelerating ions are provided and are connected to an electric source for voltage application (for upper part electrode) 7 and an electric source for voltage application (for lower part electrode) 9, respectively.

Utilizing the potential difference between the voltage applied on the upper part electrode 6 and the voltage applied on the lower part electrode 8, ions generated in plasma 5 (positive or negative charged particles) are accelerated in a direction almost vertical to a substrate 11 disposed on a substrate holding base 10 in the plasma generating and substrate treatment chamber 2 and are irradiated almost vertically to the substrate 10. The above substrate holding base 10 can be cooled by a cooling apparatus (not shown).

The plasma generating and substrate treatment chamber 2 is exhausted by an exhaust pump (not shown), and exhaust gas 12 is subjected to non-toxicity treatment by an exhaust gas treatment apparatus (not shown) and is exhausted outside the system.

One example of the pulse-time-modulated plasma generating apparatus capable of carrying out the plasma treatment process and the plasma etching process according to the present invention is shown in FIG. 2. The structure of the pulse-time-modulated plasma generating apparatus as shown in FIG. 2 is described below.

In the pulse-time-modulated plasma generating apparatus as shown in FIG. 2, an antenna 63 for generating inductively coupled plasma is rolled up in a spiral state on the upper surface of a plasma generating and substrate treatment chamber 62 provided with a port for feeding a treatment gas 61, and the antenna 63 is connected with a high frequency electric source 64 for generating plasma capable of pulse-time-modulation.

Applying a high frequency electric field from the outside of the plasma generating and substrate treatment chamber 62 in which the treatment gas 61 has been fed, plasma 65 is generated in the plasma generating and substrate treatment chamber 62. Continuously applying a high frequency electric field generates continuous plasma, and alternately repeating the application of a high frequency electric field and the stop of the application can generate pulse-time-modulated plasma. The application of a high frequency electric field and the stop of the application can be carried out by, for example, applying RF bias of 13.56 MHz in a pulse state as a discharge frequency from the high frequency electric source 64 to the antenna 63. The alternate repeating time (pulse width) of the application of a high frequency electric field and the stop of the application can be arbitrarily determined.

Further, on the lower part of a substrate holding base 70, an electrode 68 for accelerating ions is provided and is connected with an electric source 69 for voltage application. The above substrate holding base 70 can be cooled by a cooling apparatus (not shown). Furthermore, the height of the substrate 61, namely the distance between the substrate and plasma generating part can be changed by an elevating apparatus (not shown).

The inside of the plasma generating and substrate treatment chamber 62 is exhausted by an exhaust pump (not shown), and exhaust gas 72 is subjected to non-toxicity treatment by an exhaust gas treatment apparatus (not shown) and is exhausted outside the system.

The first process of the present invention is a plasma treatment process, which comprises the steps of feeding a treatment gas containing fluorine gas (F₂) to a plasma generating chamber, alternately repeating the application of a high frequency electric field and the stop of the application to generate plasma, and irradiating the plasma to a substrate and thereby carrying out substrate treatment, using, for example, a pulse-time-modulated plasma generating apparatus as shown in FIGS. 1 and 2. The present inventors have succeeded in generating pulse-time-modulated plasma of fluorine gas (F₂) for the first time.

In the pulse-time-modulated plasma of fluorine gas (F₂) obtained by the above process, the amount of negative ions (F⁻) generated is remarkably larger as compared with continuous plasma. The amount of negative ions (F⁻) generated in the pulse-time-modulated plasma of fluorine gas (F₂) is also remarkably larger as compared with the case of using sulfur hexa-fluoride gas (SF₆) as a treatment gas which case has been studied conventionally.

It is confirmed that the electron density of continuous plasma of fluorine gas (F₂) is remarkably higher as compared with the electron density of continuous plasma of sulfur hexa-fluoride gas (SF₆) with the results of measuring the electron density of the plasma. The fact that the electron density of the plasma is higher shows that the ionization effect of a treatment gas is high, and it is considered that the properties of such fluorine gas (F₂) are causes of generating large amounts of negative ions (F⁻) in the pulse-time-modulated plasma. That is, presumed is such a schema that high density electron generated during ON time of the high frequency electric field in the pulse-time-modulated plasma is dissociatively attached to fluorine gas (F₂) during OFF time of the following high frequency field to generate large amounts of negative ions (F⁻).

In the pulse-time-modulated plasma of fluorine gas (F₂), the amount of generated radical (F) having no directionality, which radical hinders fine processing, is remarkably lower as compared with the case of using sulfur hexa-fluoride (SF₆), which has been studied conventionally, as a treatment gas.

Accordingly, in the pulse-time-modulated plasma using fluorine gas (F₂) as a treatment gas, negative ions (F⁻) generated in large amounts are accelerated toward the substrate by means of an electric field from the outside, so as to have a directionality and because the amount of radical (F) having no directionality generated is low, the desired anisotropic etching can be realized.

Although fluorine gas (F₂) is a gas, which global warming potential (GWP) is zero, without greenhouse effect, the practical use thereof has scarcely been studied for plasma treatment technique and plasma etching treatment technique until now. As the reasons, the first one is that the handling of fluorine gas (F₂) is difficult because of having very high reactivity, corrosion and toxicity, and the second one, which is conventionally known, is that when plasma due to fluorine gas (F₂) is generated by a conventional process, anisotropic etching, which is an important etching property, cannot be realized.

The process of the present invention is characterized by using a gas containing fluorine gas (F₂) as a treatment gas, based on the background of the following technical progress. That is, in production process of semiconductor devices or the like, it has been possible to use fluorine gas (F₂) having high reactivity, corrosion resistance and toxicity as a processing gas, accompanying with recent new development of materials having excellent corrosion resistant and advancement of reliability and safety in gas feeding equipment. Based on such technical background, the present inventors first applied fluorine gas (F₂) to pulse-time-modulated plasma and first found that pulse-time-modulated plasma of fluorine gas (F₂) has excellent fine processability, which is a specific property such that the amount of ions generated is large and the amount of radicals generated is small. As a result, the present inventors first could make high rate anisotropic etching process with plasma using fluorine gas (F₂) into practical use.

Next, one example of a neutral beam generating apparatus capable of carrying out the plasma treatment process and the plasma etching process according to the present invention is shown in FIG. 3. The structure of the neutral beam generating apparatus as shown in FIG. 3 is described below.

In the neutral beam generating apparatus as shown in FIG. 3, a quartz made plasma generating chamber 22 has the same structure as that of the quartz made plasma generating and substrate treatment chamber 2 in the pulse-time-modulated plasma generating apparatus as shown in FIG. 1. In the plasma generating chamber 22, a port for feeding a treatment gas 21 is provided and an antenna 23 for generating inductively coupled plasma is rolled up in a coil-like state into the outer periphery of the plasma generating chamber 22 and the antenna 23 is connected with a high frequency electric source 24 for generating plasma capable of pulse-time-modulation. Plasmas 25 (continuous plasma and pulse-time-modulated plasma) can be generated by, for example, applying RF bias having an discharge frequency of 13.56 MHz from the high frequency electric source 24 to the antenna 23.

Further, on the upper and lower parts inside the plasma generating chamber 22, a carbon-made upper part electrode 26 for accelerating ions and a carbon-made lower part electrode 28 for accelerating ions (electrode for extracting a beam) are provided and are connected to an electric source for voltage application (for upper part electrode) 27 and an electric source for voltage application (for lower part electrode) 29, respectively.

Utilizing the potential difference between the voltage of the upper part electrode 26 and the voltage of the lower part electrode 28, ions generated in plasma 25 (positive or negative charged particles) is accelerated in a direction almost vertical to a substrate 33 disposed on a substrate holding base 32 inside the a stainless steel made substrate treatment chamber 30 and is irradiated to the substrate 33 almost vertically.

In order to neutralize the ion which is accelerated and extracted from the plasma 25, a plurality of fine pores, for example, pores having a diameter of 1 mm and a depth of 10 mm are provided on the lower part electrode 28. The ions accelerated by the potential difference of the voltage applied on the upper part electrode 26 and the lower part electrode 28 is neutralized by electric charge exchange or electronic separation during passing through the fine pores of the lower part electrode 28, and thereby a neutral beam 31 is generated. The neutral beam 31 is irradiated almost vertically to the substrate 33. Further, the above substrate holding base 32 can be cooled by a cooling apparatus (not shown) and the height of the substrate 33, namely the distance between the substrate and plasma generating part can be changed by an elevating apparatus (not shown).

The inside of the substrate treatment chamber 30 is exhausted by an exhaust pump (not shown), and exhaust gas 34 is subjected to non-toxicity treatment by an exhaust gas treatment apparatus (not shown) and is exhausted outside the system.

The second process of the present invention is a plasma treatment process, which comprises the steps of feeding a treatment gas containing fluorine gas (F₂) to a plasma generating chamber, alternately repeating the application of a high frequency electric field and the stop of the application to generate plasma, separately or alternately extracting negative ions or positive ions from the plasma and neutralizing them to generate a neutral beam, and irradiating the neutral beam to the substrate and thereby carrying out substrate treatment, using, for example, a neutral beam generating apparatus as shown in FIG. 3.

As described above, the present inventors first succeeded in generating pulse-time-modulated plasma of fluorine gas (F₂), and found that in the pulse-time-modulated plasma using fluorine gas (F₂) as a treatment gas, the amount of generated negative ions (F⁻) capable of giving directionality is remarkably large and the amount of generated radical (F) not having directionality is remarkably low.

However, the pulse-time-modulated plasma generating apparatus as shown in FIG. 1 described in the first process of the present invention has a problem such that, since the plasma generating chamber and the substrate treatment chamber are united in one, anisotropic etching can be realized but the damage caused by irradiating charging particles and a photon generated in the plasma to the substrate is unavoidable.

Meanwhile, in the neutral beam generating apparatus as shown in FIG. 3 described in the second process of the present invention, negative ions or positive ions are separately or alternately extracted from pulse-time-modulated plasma of fluorine gas (F₂) and neutralized to generate a neutral beam necessary for etching process and the beam is irradiated to substrate. Therefore, anisotropic etching wherein the damage caused by irradiating charging particles and photon generated in the plasma to the substrate is depressed can be realized

The process for alternately extracting negative ions and positive ions from pulse-time-modulated plasma of fluorine gas (F₂) may include a process of applying alternating current to the lower part electrode 28 as shown in FIG. 3. Specifically, in FIG. 3, to the upper part electrode 26, a direct current voltage of −50V is applied and to the power part electrode 28, an alternating current voltage of 100 V is applied and thereby negative ions and positive ions in pulse-time-modulated plasma of fluorine gas (F₂) are alternately accelerated and passed through the lower part electrode 28 with the result that a neutral beam 31 is generated.

The third process of the present invention is a plasma treatment process, which comprises the steps of feeding a treatment gas containing fluorine gas (F₂) to a plasma generating chamber, alternately repeating the application of a high frequency electric field and the stop of the application to generate a plasma, selectively extracting only negative ions from the plasma and neutralizing them to generate a neutral beam, and irradiating the neutral beam to the substrate and thereby carrying out substrate treatment, using, for example, a neutral beam generating apparatus as shown in FIG. 3.

As described above, the neutralization of negative ions proceeds by separation of electrons adhered on gas atoms and molecules so that a neutral beam can be generated with low energy and high efficiency as compared with neutralization of positive ions by electric charge exchange. In the case of extracting only negative ions and neutralizing them in this manner, the density of a neutral beam generated is lowered, while the proportion of neutralization of a neutral beam is increased. Therefore, charged particles remained in the neutral beam is decreased as compared with the process for extracting both of positive and negative ions and neutralizing them. As a result, anisotropic etching such that damage caused by irradiating charged particles and photon generated in plasma to a substrate is further depressed can be realized.

In the process for generating pulse-time-modulated plasma using a gas containing fluorine gas (F₂) as a treatment gas, the concentration of fluorine gas (F₂) contained in the treatment gas can be arbitrarily determined in accordance with the objects such as plasma treatment process or the like, and further in order to obtain high density plasma and a neutral beam with higher efficiency, it is preferred to use fluorine gas (F₂) having a higher concentration, and further, it is particularly preferred to use 100% by volume of fluorine gas (F₂).

As a treatment gas, chlorine gas (Cl₂), which is a gas having no greenhouse effect, similar to fluorine gas (F₂) is also preferably used in the kind of a gas for mixing with fluorine gas (F₂). In pulse-time-modulated plasma using the mixed gas of fluorine gas (F₂) and chlorine gas (Cl₂), changing the mixing ratio of fluorine gas (F₂) and chlorine gas (Cl₂), the mixing ratio of F (F⁻ ion and neutral F beam) and Cl (Cl⁻ ion and neutral Cl beam) can be easily changed, and plasma treatment or plasma etching treatment utilizing the difference of chemical properties or the difference of particle size between Fluorine (F) and chlorine (Cl) can be carried out.

For example, in etching of gate electrode poly-silicon, the etching reaction is proceeded rapidly by enhancing the fluorine gas (F₂) concentration in the initial etching step in which high rate etching is required, and process optimization utilizing the difference of the chemical properties of fluorine (F) and chlorine (Cl) can be performed by enhancing the concentration of chlorine gas (Cl₂) in the later etching step in which etching having high selectivity is required. Because the particles of fluorine (F) are smaller as compared with those of chlorine (Cl), it has a possibility of forming an etching process having low damage. It is preferred that the mixing ratio of fluorine gas and chlorine gas in the treatment gas be determined to an optimum ratio in accordance with the object for a plasma treatment process or plasma etching process.

As a feeding source of fluorine gas (F₂), it is possible to select and use any supplying system, for example, a fluorine gas cylinder filled with high pressure, a fluorine gas generating apparatus utilizing electrolysis reaction of hydrogen fluoride or thermal decomposition reaction of a metal fluoride or the like. Among the systems, the system utilizing thermal decomposition reaction of a solid metal fluoride is particularly preferred because the safety is higher and fluorine gas (F₂) having a higher purity can be supplied.

In generating a plasma using a treatment gas containing fluorine gas (F₂), the gas pressure in the plasma generating chamber, which can be optionally determined in accordance with the object for a plasma treatment method or the like, is from 0.1 to 100 Pa, preferably 0.3 to 10 Pa, particularly preferably 0.5 to 5 Pa. When the gas pressure is determined in the above range, high density plasma and a neutral beam can be prepared with high efficiency. When the gas pressure in the plasma generating chamber is lower than the above range, it is difficult to generate high density plasma, while when it is over the range, the generation efficiency of plasma and a neutral beam tends to be lowered.

In the process for generating the pulse-time-modulated plasma by alternately repeating the application (ON) of a high frequency electric field and the stop of the application (OFF) thereof to make a treatment gas into plasma, the combination of ON time and OFF time can be optionally determined, and it is general to employ a process of repeating the ON time and OFF time in several ten μsec order. In the case of using the gas containing fluorine gas (F₂) as a treatment gas according to the present invention, the OFF time is from 20 to 100 μsec, preferably 40 to 90 μsec, particularly preferably 50 to 70 μsec. When the OFF time is shorter than the above range, the generation of negative ions tends to be insufficient, while when it is over the above range, the electron density in the plasma is lowered to cause an effect such that discharging is difficult in the next ON time or an effect such that electron temperature is rapidly increased in the ON time, and thereby electrons are increased, with the result that the effect of pulse-time-modulation tends to be inhibited.

The plasma treatment process of the present invention as described above is preferably used to a process of fluorination treatment for precisely fluorinating the substrate surface (precisely control the depth of fluorine penetration into the substrate surface or gradient of fluorine concentration), a process of plasma etching for finely processing the surface of various substrates with low damage and high precision (anisotropy, selectivity, high rate) and other processes. The plasma treatment process, further, can be preferably used as a plasma etching technique of silicon and a silicon compound which technique is important in the production step of semiconductor devices or MEMS devices. Examples of the above silicon compound may include silicon oxide, silicon nitride, a silicate (such as glass-like sodium silicate, etc) or the like.

In particular, as compared with a process of using sulfur hexa-fluoride (SF₆), which process has been studied conventionally, the process of the present invention is very favorable as a fluorine (F⁻ ion and neutral F beam) source applicable to coming plasma etching techniques because favorable plasma and neutral beam for etching reaction can be generated.

Therefore, the present invention first enables forming the optimum process utilizing the difference of the chemical properties and particle size between fluorine (F) and chlorine (Cl) by the combined pulse-time-modulated plasma of chlorine gas (Cl₂) used as a chlorine (Cl⁻ ion and neutral Cl beam) source with the process of the present invention.

For example, in accordance with a substance to be etched and the etching object in each etching process, neutral F beam and neutral Cl beam are used properly or are mixed, so as to enhance the etching rate or the selectivity. Accordingly, the process of the present invention is sufficiently applicable to processes of etching new materials (Hf type high-k and all metal compounds containing noble metals) to be used in the coming new processes.

Therefore, utilizing the fine processing technique of the present invention, ultra high property-having semiconductor devices or new MEMS devices, which have not been produced until now, can be produced.

Moreover, because of using inexpensive fluorine gas (F₂) having no greenhouse effect as a treatment gas, the process of the present invention is harmonious with the environment and highly practical so that the technical value of the process is very high.

### EXAMPLES

Hereinafter, the present invention is described in more detail with reference to the following examples, but it should not be limited by these examples.

### Example 1

Using a plasma and neutral beam analysis apparatus as shown in FIG. 4, a continuous plasma, pulse-time-modulated plasma and neutral beam were generated from fluorine gas (F₂) and then the generated continuous plasma, pulse-time-modulated plasma and neutral beam were analyzed using QMS (quadrupole mass spectrometer), a microwave interferometer, an emission spectrometer, a Faraday cup and a calorimeter.

At first, the structure of the plasma and neutral beam analysis apparatus as shown in FIG. 4 is described below. In the plasma and neutral beam analysis apparatus as shown in FIG. 4, a quartz made plasma generating chamber 42 has the same structure as the quartz made plasma generating and substrate treatment chamber 2 in the pulse-time-modulated plasma generating apparatus as shown in FIG. 1. The plasma generating chamber 42 is provided with a port for feeding a treatment gas 41, and an antenna 43 for generating inductively coupled plasma is rolled up in a coil-like state to the outer periphery of the plasma generating chamber, and the antenna 43 is connected with a high frequency electric source 44 for generating plasma capable of pulse-time-modulation.

Plasma 45 (continuous plasma and pulse-time-modulated plasma) can be generated by, for example, applying RF bias having a discharge frequency of 13.56 MHz from the high frequency electric source 44 to the antenna 43.

Further, on the upper and lower parts inside the plasma generating chamber 42, a carbon-made upper part electrode 46 for accelerating ions and a carbon-made lower part electrode 48 for accelerating ions (electrode for extracting a beam) are provided and are connected to an electric source for voltage application (for upper part electrode) 47 and an electric source for voltage application (for lower part electrode) 49, respectively.

Utilizing the potential difference between the voltage of the upper part electrode 46 and the voltage of the lower part electrode 48, ions (positive or negative charged particles) generated in the plasma 45 is accelerated in a direction almost vertical to a measuring apparatus 52 disposed in a stainless steel made measuring chamber 50 and is irradiated almost vertically to the measuring apparatus 52.

In order to neutralize ions which are accelerated and extracted from the plasma 45, a plurality of pores (pore having a diameter of 1 mm and a depth of 10 mm) are provided in an area equivalent of 50% of the electrode area on the lower part electrode 48. The ion accelerated by the potential difference of the voltage applied on the upper part electrode 46 and the voltage applied on the lower part electrode 48 is neutralized by electric charge exchange, electron separation or the like during passing through the fine pores of the lower part electrode 48, to generate a neutral beam 51. The neutral beam 51 is irradiated in a direction almost vertical to the measuring apparatus 52.

The stainless steel measuring chamber 50 is exhausted by a turbo molecular pump for exhausting (not shown), and the exhaust gas 53 is subjected to non-toxicity treatment by an exhaust gas treating apparatus (not shown) to exhaust outside the system.

<Experiment 1>

Into the plasma generating chamber 42 in the plasma and neutral beam analysis apparatus as shown in FIG. 4, 30 ml/min of 100% by volume fluorine gas (F₂) was introduced as a treatment gas 41 and RF bias having a discharge frequency of 13.56 MHz (500 W or 1 kW) was continuously applied from the high frequency electric source 44 to the antenna 43, to generate a continuous plasma. In this time, the upper part electrode 46 and the lower part electrode 48 were in an earth connection state without application of a voltage. The pressure of the plasma generating chamber 42 was 1 Pa in the time of plasma generating. As the fluorine gas (F₂), fluorine gas (F₂) generated by K₃NiF₇ thermal decomposition reaction by heating a vessel filled with K₃NiF₇, which is a metal fluoride, at 350° C. is used.

In the measuring chamber 50, QMS (measuring apparatus 52) was provided so that a gas introducing port of the QMS was disposed at the position about 200 mm from the lower part in the lower part electrode 48, and measurement of the plasma 45 was carried out. In the case that the upper part electrode 46 and the lower part electrode 48 were in an earth connecting state without application of a voltage as described above, the plasma 45 generated in the plasma generating chamber 42 passed through the lower part electrode 48 while it kept the plasma composition and it was scarcely neutralized, and then was flown into the QMS. The measuring chamber 50 was rapidly exhausted by a turbo molecular pump for exhausting, the exhaust gas 53 was subjected to non-toxicity treatment by the exhaust gas treatment apparatus and exhausted outside the system.

Through the above process, negative ions contained in the continuous plasma of fluorine gas (F₂) were analyzed with QMS measurement. The results of the analysis of RF bias=500 W is shown in FIG. 5 and the results of the analysis of RF bias=1 kW is shown in FIG. 6.

<Experiment 2>

The procedure of Experiment 1 in Example 1 was repeated except that into the plasma generating chamber 42 in the plasma and neutral beam analysis apparatus as shown in FIG. 4, 30 ml/min of 100% by volume fluorine gas (F₂) was introduced as a treatment gas 41 and RF bias having a discharge frequency of 13.56 MHz (2 kW during the ON time or 500 W during the ON time) was applied in a pulse-like state from the high frequency electric source 44 to the antenna 43, to generate a pulse-time-modulated plasma, the ON time/OFF time in pulse-time-modulation are 50 μsec/50 μsec and the voltage to be applied on the antenna 43 was modulated in a pulse-like state to generate a pulse-time-modulated plasma.

Through the above process, negative ions contained in the pulse-time-modulated plasma of fluorine gas (F₂) were analyzed with QMS measurement. The results of the analysis of RF bias=2 kW (during the ON time) are shown in FIG. 5 and the results of the analysis of RF bias=1 kW (during the ON time) are shown in FIG. 6.

As is clear from FIGS. 5 and 6, in the continuous plasma of fluorine gas (F₂), the amount of F⁻ ion generated was small, while in the pulse-time-modulated plasma of fluorine gas (F₂), the amount of F⁻ ion generated was remarkably increased.

<Experiment 3>

In the plasma generating chamber 42 of the plasma and neutral beam analysis apparatus as shown in FIG. 4, 30 mL/min of 100% by volume fluorine gas (F₂) was introduced as a treatment gas 41, RF bias having a discharge frequency of 13.56 MHz was continuously applied from the high frequency electric source 44 to the antenna 43 to generate a continuous plasma. In this time, the upper part electrode 46 and the lower part electrode 48 were in an earth connection state without application of a voltage. In the time of plasma generating, the pressure inside the plasma generating chamber 42 was 1 Pa. As the fluorine gas (F₂), fluorine gas (F₂) generated by K₃NiF₇ thermal decomposition reaction by heating a vessel filled with K₃NiF₇, which is a metal fluoride, at 350° C. is used.

A microwave interferometer (not shown) was set outside the plasma generating chamber 42 and the electron density of the continuous plasma of fluorine gas (F₂) was measured. The output of a high frequency electric field for application to the antenna 43 was changed to generate a plasma, and with regard to the electron density of the continuous plasma of fluorine gas (F₂), the RF output dependency was measured. The analysis results are shown in FIG. 7.

FIG. 7 also shows the results of sulfur hexa-fluoride (SF₆) of Experiment 2 in Comparative Example 1 as described later for comparison. As is clear from FIG. 7, it was found that in the continuous plasma of fluorine gas (F₂), the electron density was higher as compared with sulfur hexa-fluoride (SF₆), and even in the case that the RF output was about 400 W, the electron density was not less than 1.0×10¹¹/cm³. Further, it was also found that the electron density increases monotonously in accordance with the increase of the RF output. The fact that the electron density of the continuous plasma is high shows that the electron density of the high frequency electric field in the pulse-time-modulated plasma during the ON time is high.

Therefore, as described above, it is expected that in the pulse-time-modulated plasma, electrons having a high density generated during the ON time were dissociatively adhered on fluorine gas (F₂) during the OFF time of the following high frequency electric field to generate a large amount of negative ion (F⁻).

<Experiment 4>

In the plasma generating chamber 42 of the plasma and neutral beam analysis apparatus as shown in FIG. 4, 30 mL/min of fluorine gas (F₂) and 1.5 mL/min of argon gas were introduced as a treatment gas 41, RF bias having a discharge frequency of 13.56 MHz was continuously applied from the high frequency electric source 44 to the antenna 43 to generate a continuous plasma. In this time, the upper part electrode 46 and the lower part electrode 48 were in an earth connection state without application of a voltage. In the time of plasma generating, the pressure inside the plasma generating chamber 42 was 1 Pa. As the fluorine gas (F₂), fluorine gas (F₂) generated by K₃NiF₇ thermal decomposition reaction by heating a vessel filled with K₃NiF₇, which is a metal fluoride, at 350° C. is used.

An emission spectrometer (not shown) was set outside the plasma generating chamber 42 and the emission spectrum of the continuous plasma of fluorine gas (F₂) was measured. The output of a high frequency electric field for application to the antenna 43 was changed to generate plasma, and with regard to the emission spectrum of the continuous plasma of fluorine gas (F₂), the RF output dependency was measured. From the emission spectrum obtained in each plasma condition, the intensity ratio of the emission peak (750.4 nm) of argon radical (Ar) to the emission peak (703.7 nm) of fluorine radical (F) [IF(703.7 nm)/IAr (750.4 nm)] was determined. It is possible to conduct relative comparison of the amount of fluorine radical (F) by the mutual comparison of IF(703.7 nm)/IAr (750.4 nm). The above method is an analysis procedure, which is generally called as emission actinometry. The analysis results are shown in FIG. 8.

FIG. 8 also shows the results of sulfur hexa-fluoride (SF₆) of Experiment 3 in Comparative Example 1 as described later for comparison. As is clear from FIG. 8, it was found that in the continuous plasma of fluorine gas (F₂), the value of IF(703.7 nm)/IAr (750.4 nm) was very low as compared with sulfur hexa-fluoride gas (SF₆), and even in the case of increasing the RF output to from 300 to 1000 W, the value of IF(703.7 nm)/IAr (750.4 nm) showed an almost definite value. That is, in the continuous plasma of fluorine gas (F₂), the fluorine (F) radical amount was very small in the RF output region where the measurement was carried out.

<Experiment 5>

The procedure of Experiment 2 in Example 1 was repeated except that in the plasma and neutral beam analysis apparatus as shown in FIG. 4, −100V of a direct current voltage was applied on the upper part electrode 46 and −50V of a direct current voltage was applied on the lower part electrode 48, to generate a pulse-time-modulated plasma of fluorine gas (F₂).

On the upper part electrode 46 and the lower part electrode 48, such potential difference was provided and thereby a large amount of negative ion (F⁻) generated inside the pulse-time-modulated plasma was accelerated in the direction almost vertical to the lower part electrode 48, and neutralized by separation of adhered electrons in the step of passing through the fine pores of the lower part electrode 48. As a result, a neutral beam 51 was generated and flown into the QMS (measuring apparatus 52) present in the measuring chamber 50.

By the above method, negative ions were selectively extracted from the pulse-time-modulated plasma of fluorine gas (F₂) and neutralized to generate a neutral beam. Negative ions remained in the generated neutral beam, namely un-neutralized negative ions were analyzed by the QMS measurement. The results are shown in FIG. 10. For the comparison, with regard to the pulse-time-modulated plasma of fluorine gas (F₂) in Experiment 2 of Example 1, the results of the negative ion analysis are also shown in FIG. 10.

As is clear from FIG. 10, in the neutral beam generated by selectively extracting negative ions from the pulse-time-modulated plasma of fluorine gas (F₂) and neutralizing them, un-neutralized negative ions (F⁻) remained were scarcely contained. That is, the results show that the neutralization rate of the neutral beam generated by selectively extracting negative ions from the pulse-time-modulated plasma of fluorine gas (F₂) and neutralizing them is very high, namely the neutralization has a high efficiency.

<Experiment 6>

The procedure of Experiment 5 in Example 1 was repeated except that as a measuring apparatus 52 set in the measuring chamber 50 as shown in FIG. 4, a Faraday cup (measuring apparatus 52) was used and set so that a gas introducing port of the Faraday cup was disposed at the position about 20 mm from the lower part in the lower part electrode 48, to generate a neutral beam by selectively extracting negative ions from the pulse-time-modulated plasma of fluorine gas (F₂) and neutralizing them. With regard to negative ions remained in the generated neutral beam, namely un-neutralized negative ions, the current density was measured using the Faraday cup. As a result, it was confirmed that the current density of negative ions remained in the neutral beam was less than the detectable lower limit (0.4 μA/cm²) and was very low.

From the results of measurement with the QMS and the Faraday cup, it was cleared that in the pulse-time-modulated plasma of fluorine gas (F₂), a large amount of F⁻ ions are generated, the F⁻ ions generated in a large amount in the plasma can be neutralized with high efficiency and the neutralization rate near to almost 100% is realized.

<Experiment 7>

The procedure of Experiment 5 in Example 1 was repeated except that as the measuring apparatus 52 disposed in the measuring chamber 50 as shown in FIG. 4, a calorimeter was disposed, to generate a neutral beam by selectively extracting negative ions from a pulse-time-modulated plasma of fluorine gas (F₂) and neutralizing them. The flux of the resulting neutral beam was measured by the calorimeter. It is considered that the kinetic energy of the beam flown into the calorimeter is almost completely thermal exchanged in the calorimeter so that the change of the output voltage of the calorimeter (ΔV/15 sec) was taken as a flux of the neutral beam. The results are shown in FIG. 11.

In FIG. 11, the results of sulfur hexa-fluoride gas (SF₆) in Experiment 4 of Comparative Example 1 as described later for comparison are also shown. As is clear from FIG. 11, it was found that the flux of the neutral beam, which beam was generated by selectively extracting negative ions from the pulse-time-modulated plasma of fluorine gas (F₂) and neutralizing them, was five times or more as large as that of sulfur hexa-fluoride gas (SF₆).

### Example 2

Plasma etching for a substrate was carried out by a pulse-time-modulated plasma of fluorine gas (F₂), the etching rate of silicon (Si) was measured and the etching form was observed.

<Experiment 1>

Using a pulse-time-modulated plasma generating apparatus as shown in FIG. 2, 30 mL/min of the 100% by volume fluorine gas (F₂) same as one used in Example 1 was introduced as a treatment gas 61 into a plasma generating and substrate treatment chamber 62, and RF bias (1 kW) having a discharge frequency of 13.56 MHz was applied from a high frequency electric source 64 to an antenna 63 to generate a continuous plasma 65.

To a carbon made electrode for accelerating ion 68, RF bias of 1 MHz was applied with an output of 50 W from an electric source for applying voltage 69. By applying the RF bias to the carbon made electrode for accelerating ion 68 in this manner, positive and negative ions generated in the plasma 65 were accelerated in the direction almost vertical to a substrate holding base 70 and irradiated on the substrate.

The substrate holding base 70 was disposed at the position 50 mm from the lower part of the plasma generating part and cooled to −20° C. On the substrate holding base 70, a silicon (Si) substrate that an aluminum thin film was deposited on the surface thereof as an etching mask was disposed and the substrate was subjected to plasma etching by the plasma 65. The etching rate was determined in the following manner. Etching treatment was carried out several times by changing only the etching treatment time and then the etching depth was measured using a step measuring apparatus. The etching rate obtained in the experiment is shown in Table 1.

<Experiment 2>

The procedure of Experiment 1 in Example 2 was repeated except that RF bias of 1 kW having a discharge frequency of 13.56 MHz (during the ON time) was applied in a pulse state from the high frequency electric source 64 to the antenna 63, to generate pulse-time-modulated plasma 65, and thereby plasma etching for the substrate was carried out. In this procedure, the ON time/OFF time in the pulse-time-modulation were 50 μsec/50 μsec. The etching rate obtained in the experiment is shown in Table 1. FIG. 9 shows an image of the etching form observed by SEM (scanning electron microscope).

TABLE 1

| | Si etching rate |
|---|---|
| | (nm/min) |
| Experiment 1 Continuous plasma | 840 |
| Experiment 2 Pulse-time-modulated plasma | 1220 |

As is clear from Table 1, it was found that the etching rate of the pulse-time-modulated plasma of fluorine gas (F₂) (RF output=1 kW (during the ON time) was about 1.5 times higher than the etching rate of the continuous plasma of fluorine gas (F₂) (RF output=1 kW) even though the substantial plasma power thereof was half (0.5 time) of that of the continuous plasma of fluorine gas (F₂). Furthermore, from FIG. 9, it was substantiated that the Si etching can proceed vertically without the formation of a sidewall protecting film. Moreover, from these results, it is also revealed that a large amount of negative ions (F⁻) generated in the plasma by pulse modulating the plasma of fluorine gas (F₂) greatly contributes to Si etching. In the etching with the pulse-time-modulated plasma of fluorine gas (F₂), while favorable vertical processing is kept, the etching rate is over 1 μm/min. These results satisfy the processing conditions which are required in the production processes of MEMS and the like.

### Example 3

From pulse-time-modulated plasma of fluorine gas (F₂), negative ions were selectively extracted and neutralized to generate a neutral beam. By the neutral beam, plasma etching of a substrate was carried out. In order to examine the composition of the neutral beam, etching rates of polysilicon (Poly-Si) and SiO₂ were measured using electrodes of extracting beams having a different F radical-adhering coefficient, and further the etching form of Poly-Si was observed.

<Experiment 1>

Using the neutral beam generating apparatus as shown in FIG. 3, 30 mL/min of the 100% by volume fluorine gas (F₂) same as that used in Example 1 was introduced as a treatment gas 21 to a plasma generating chamber 22, and RF bias of 1 kW having a discharge frequency of 13.56 MHz (during the ON time) was applied in a pulse state from a high frequency electric source 24 to an antenna 23, to generate pulse-time-modulated plasma. In this procedure, the ON time/OFF time in the pulse-time-modulation were 50 μsec/50 μsec.

To the upper part electrode 26, a direct current voltage of −100V was applied and to the power part electrode 28, a direct current voltage of −50 V was applied. By providing such potential difference, negative ions (F⁻) generated in the pulse-time-modulated plasma was accelerated in the direction almost vertical to the lower part electrode 28, neutralized by separation of adhered electrons in the step of passing through fine pores of the lower part electrode 28 to generate a neutral beam 31 and the neutral beam were flown into a stainless steel made substrate treatment chamber 30.

A substrate holding base 32 of the substrate treatment chamber 30 was disposed at the position 20 mm from the lower part of the lower part electrode 28 and cooled to −20° C. A substrate having a Poly-Si film or SiO₂ film on its surface was disposed on the substrate holding base 32 and plasma etching thereof was carried out by the above neutral beam 31. The etching rates of Poly-Si and SiO₂ were determined in the following manner. Etching treatment was carried out several times by changing only the etching treatment time and then the etching depth was measured using a step measuring apparatus.

Next, the etching rates of Poly-Si and SiO₂ were measured in the above conditions except for using an electrode for extracting beam in which the surface of the lower part electrode 28 was coated by spraying alumina. These measurement results are inclusively shown in Table 2.

TABLE 2

Etching rate (nm/min)

| | Poly-Si | SiO₂ |
|---|---|---|
| Carbon made electrode | 9.5 | 1.42 |
| Alumina sprayed electrode | 20.2 | 5.24 |

Spraying alumina on the carbon electrode surface, the adhesion of F radical on the surface of the electrode for extracting beam and the reaction thereof can be depressed. Therefore, when the alumina sprayed electrode is used as an electrode for extracting beam, F radicals present in the plasma are hardly disappeared by the reaction with the electrode and thereby, as they are, mingle into the neutral beam.

Accordingly, in the case of using the carbon made electrode and in the case of using the alumina sprayed electrode, the proportion that F radicals contribute to the etching properties for a substrate can be presumed by measuring the etching rate. Namely, in the case that a large amount of radicals are present in the neutral beam, it is considered that the etching rate in the case of using the alumina sprayed electrode in which the disappearance of radicals is depressed is remarkably larger than the etching rate in the case of using the carbon electrode in which radicals are disappeared.

Furthermore, it is considered that although the Poly-Si is spontaneously etched not only by neutral F beam but also by diffusing F radicals, the SiO₂ etching is performed by a large contribution of neutral beam having large kinetic energy. Therefore, measuring the etching rates both of the Poly-Si and SiO₂, the proportion of F radicals mingled into the neutral F beam can be presumed. Namely, in the case that a large amount of radicals are present in the neutral beam, the etching rate of the Poly-Si is larger, while the etching rate of the SiO₂ is smaller.

As is clear from Table 2, in the neutral beam generated by selectively extracting negative ions from the pulse-time-modulated plasma of fluorine gas (F₂) and neutralizing them, when the case of using a carbon made electrode as an electrode for extracting beam with the case of using an alumina sprayed electrode are compared, it was found that with regard to the etching rate of the Poly-Si, the difference there between was not large. Namely, it is revealed that in the neutral beam generated by selectively extracting negative ions from the pulse-time-modulated plasma of fluorine gas (F₂) and neutralizing them, the amount of F radicals not having directionality generated is small. Simultaneously, this result shows that not only in the neutralized neutral beam but also in the pulse-time-modulated plasma of fluorine gas (F₂) per se, the amount of F radicals generated is small.

<Experiment 2>

Using the neutral beam generating apparatus as shown in FIG. 3, the Poly-Si was etched by the same process as in Experiment 1 of Example 3 and the etching form was evaluated by observation with SEM (scanning electron microscope). The sample used for etching form evaluation was prepared by forming a SiO₂ film (300 nm) on a Si substrate by thermal oxidation treatment and depositing thereon a polysilicon (Poly-Si) film having a thickness of 150 nm. As an etching mask, on the Poly-Si surface, an antireflection film and a resist were applied and subjected to exposure and development treatment. In order to evaluate the etching form, the etching treatment time was determined to the condition such that the etching is carried out too much by 20%, that is, the etching treatment time is determined to the time capable of etching the Poly-Si film thickness of 180 nm which is 1.2 times as much as the thickness of 150 nm of the Poly-Si film. With regard to the case of using the carbon electrode and the case of using the alumina sprayed electrode as the electrode of extracting beam, the results are shown in FIG. 12 and FIG. 13 respectively.

As is clear from the SEM observation results as shown in FIG. 12 and FIG. 13, in the neutral beam generated by selectively extracting negative ions from the pulse-time-modulated plasma of fluorine gas (F₂) and neutralizing them, anisotropic etching with high accuracy was realized and it verifies the supposition that in the neutral beam, the amount of F radicals generated is small, disclosed in the results of Experiment 1 in Example 3.

### Example 4

By the neutral beam generated by selectively extracting negative ions from the pulse-time-modulated plasma of fluorine gas (F₂) and neutralizing them, plasma etching for a substrate was carried out. The substrate used herein was prepared by depositing a polysilicon (Poly-Si) film having a gate length of 50 nm which length is desired in the coming etching.

The procedure of Experiment 1 in Example 3 was repeated except that the neutral beam generating apparatus as shown in FIG. 3 was used and the lower part electrode 28 was in a earth connection state and thereby a Poly-Si film was etched. The etching rate and the etching form were evaluated by observation with SEM (scanning electron microscope). The electrode of extracting beam 28 was a carbon electrode. The results are shown in FIG. 14.

As is clear from FIG. 14, by the neutral beam generated by selectively extracting negative ions from the pulse-time-modulated plasma of fluorine gas (F₂) and neutralizing them, the formation of a Polysilicon (Poly-Si) pattern having a width of 50 nm was accomplished. Further, the etching rate was 29.4 nm/min so that the practical rate could be attained in processing gate electrodes.

### Comparative Example 1

Pulse-time-modulated plasma was generated using a sulfur hexa-fluoride gas (SF₆) as a treatment gas and a neutral beam extracted from the pulse-time-modulated plasma was generated, and then the analyses thereof were carried out by various measuring apparatuses. The comparison with Example 1 as described was carried out and it was confirmed that the case of using fluorine gas (F₂) as a treatment gas was superior.

<Experiment 1>

The procedure of Experiment 2 in Example 1 was repeated except for using a sulfur hexa-fluoride gas (SF₆) as a treatment gas and negative ions in the pulse-time-modulated plasma of sulfur hexa-fluoride gas (SF₆) were analyzed by QMS measurement. The analysis results are shown in FIG. 15. For comparison, FIG. 15 also shows the analysis results of the negative ions in the pulse-time-modulated plasma of fluorine gas (F₂) in Experiment 2 of Example 1.

As is clear from FIG. 15, in the pulse-time-modulated plasma of sulfur hexa-fluoride gas (SF₆), F⁻ ions were scarcely generated and the amount of F ions was remarkably smaller as compared with the pulse-time-modulated plasma of fluorine gas (F₂)

<Experiment 2>

The procedure of Experiment 3 in Example 1 was repeated except for using sulfur hexa-fluoride gas (SF₆) as a treatment gas and the electron density of continuous plasma of sulfur hexa-fluoride gas (SF₆) was measured. The analysis results are shown in FIG. 7.

FIG. 7 also shows the results of fluorine gas (F₂) in Experiment 3 of Example 1 as described for comparison. From FIG. 7, it was confirmed that the continuous plasma of fluorine gas (F₂) has a larger electron density as compared with that of sulfur hexa-fluoride gas (SF₆), namely, the ionization efficient of fluorine gas (F₂) is higher than that of sulfur hexa-fluoride gas (SF₆).

<Experiment 3>

The procedure of Experiment 4 in Example 1 was repeated except for using, as a treatment gas, 30 mL/min of sulfur hexa-fluoride gas (SF₆) and 1.5 mL/min of argon gas and the amount of fluorine radical (F) of continuous plasma of sulfur hexa-fluoride gas (SF₆) was measured. The analysis results are shown in FIG. 8.

FIG. 8 also shows the results of fluorine gas (F₂) in Experiment 4 of Example 1 as described for comparison. From FIG. 8 it was confirmed that the continuous plasma of fluorine gas (F₂) has a very smaller value of the rate of IF (703.7 nm)/IAr (750.4 nm) as compared with that of sulfur hexa-fluoride gas (SF₆), namely, the continuous plasma of fluorine gas (F₂) has a low content of fluorine (F) radical.

<Experiment 4>

The procedure of Experiment 7 in Example 1 was repeated except for using sulfur hexa-fluoride gas (SF₆) as a treatment gas and then with regard to the resulting the neutral beam generated by selectively extracting negative ions from the pulse-time-modulated plasma of sulfur hexa-fluoride gas (SF₆) and neutralizing them, the flux was measured. The results are shown in FIG. 11.

FIG. 11 also shows the results of fluorine gas (F₂) in Experiment 7 of Comparative Example 1 as described for comparison. As is clear from FIG. 11, it was confirmed that the neutral beam generated by selectively extracting negative ions from the pulse-time-modulated plasma of fluorine gas (F₂) and neutralizing them, has a flux 5 times or more as large as that of sulfur hexa-fluoride gas (SF₆).

### Comparative Example 2

Using pulse-time-modulated plasma generated using a sulfur hexa-fluoride gas (SF₆) as a treatment gas, plasma etching for a substrate was carried out, and then the etching rate of a silicon (Si) substrate was measured and the etching form was observed. In comparison with Example 2 as described above, it was confirmed that the case of using fluorine gas (F₂) as a treatment gas was superior.

<Experiment 1>

The procedure of Experiment 2 in Example 1 was repeated except for using a sulfur hexa-fluoride gas (SF₆) as a treatment gas and thereby continuous plasma of sulfur hexa-fluoride gas (SF₆) was generated and plasma etching for a silicon (Si) substrate was carried out. The etching rate was determined in the following manner. Etching treatment was carried out several times by changing only the etching treatment time and then the etching depth was measured using a step measuring apparatus. The etching rate obtained in the experiment is shown in Table 3.

<Experiment 2>

The procedure of Experiment 2 in Example 2 was repeated except for using sulfur hexa-fluoride gas (SF₆) as a treatment gas and thereby, etching for a silicon (Si) substrate was carried out by the pulse-time-modulated plasma. The etching rate obtained in the experiment is shown in Table 3. Furthermore, the image of the etching form observed by SEM (scanning electron microscope) is shown in FIG. 16.

TABLE 3

| | Si etching rate |
|---|---|
| | (nm/min) |
| Experiment 1 Continuous plasma | 4760 |
| Experiment 2 Pulse-time-modulated plasma | 3590 |

As is clear from Table 3, it was found that as compared with the etching rate with the continuous plasma (RF output=1 kW) of sulfur hexa-fluoride gas (SF₆), the etching rate of the pulse-time-modulated plasma (RF output=1 kW during the ON time) is smaller. This fact is largely different from the results of Experiments 1 and 2 in Example 2 (Table 1) as described above. The fact that the etching rate of the pulse-time-modulated plasma of sulfur hexa-fluoride gas (SF₆) is smaller than the etching rate of the continuous plasma is considered due to such reasons that one reaction species mainly contributing to the etching reaction of the sulfur hexa-fluoride gas (SF₆) plasma is radical and in the pulse-time-modulated plasma, the amount of the radical generated is smaller as compared with that in the continuous plasma. Furthermore, from FIG. 16, it was also confirmed that in the pulse-time-modulated plasma of sulfur hexa-fluoride gas (SF₆), large undercuts (side etching) were caused in the Si etching, namely, isotropic etching proceeded.

### Comparative Example 3

### Experiment 1

The procedure of Experiment 1 in Example 3 was repeated except for using sulfur hexa-fluoride gas (SF₆) as a treatment gas and thereby pulse-time-modulated plasma of sulfur hexa-fluoride gas (SF₆) was generated and neutral beam was generated by selectively extracting negative ions from the pulse-time-modulated plasma and neutralizing them. The etching rates for polysilicon (Poly-Si) and SiO₂ were measured using the neutral beam. The results are shown in Table 4.

TABLE 4

Etching rate (nm/min)

| | Poly-Si | SiO₂ |
|---|---|---|
| Carbon made electrode | 49.2 | 0.74 |
| Alumina sprayed electrode | 1356 | 3.7 |

As is clear from Table 4, with regard to the neutral beam generated by selectively extracting negative ions from the pulse-time-modulated plasma of sulfur hexa-fluoride (SF₆) and neutralizing them, when the case of using the carbon made electrode as an electrode for extracting beam was compared with the case of using the alumina sprayed electrode as an electrode for extracting beam, it was found that the difference of the etching rate for Poly-Si was very large. Namely, this result shows that in conventional pulse-time-modulated plasma of sulfur hexa-fluoride (SF₆), the amount of F radical generated in the plasma is very large as compared with the pulse-time-modulated plasma of fluorine (F₂).

Furthermore, when Table 2 is compared with Table 4, with regard to the etching rate for SiO₂, which is considered to have a large contribution by neutral F beam having large kinetic energy, the etching rate in the case of using fluorine gas (F₂) is higher than the etching rate in the case of using sulfur hexa-fluoride gas (SF₆) even in any of the case of using the carbon made electrode and the case of using the alumina sprayed electrode. This results shows that the pulse-time-modulated plasma of fluorine gas (F₂) has a remarkably excellent efficiency of generating neutral F beam as compared with the conventional pulse-time-modulated plasma of sulfur hexa-fluoride gas (SF₆).

### Experiment 2

The procedure of Experiment 2 in Example 3 was repeated except for using sulfur hexa-fluoride gas (SF₆) as a treatment gas and thereby Poly-Si was etched and the etching form was evaluated by observation with SEM (scanning electron microscope). The results in the case of using the carbon electrode as an electrode for extracting beam are shown in FIG. 17 and the results in the case of using the alumina sprayed electrode are shown in FIG. 18.

In the SEM image as shown in FIGS. 17 and 18, clear side etching was observed under the etching mask. Such side etching shows that the amount of radicals (F atom not having directionality) mingled into the neutral beam is large. Particularly, in the case of using the alumina sprayed electrode, side etching remarkably appeared. This result shows that the radical amount is large as compared with the case of using the carbon electrode.

Therefore, in the neutral beam generated by selectively extracting negative ions from the pulse-time-modulated plasma of sulfur hexa-fluoride (SF₆) and neutralizing them, the etching form was isotropic and it was revealed that anisotropic etching cannot be attained. That is, this fact supports the effect in Experiment 1 of Comparative Example 3 such that in the neutral beam using sulfur hexa-fluoride (SF₆), the amount of F radical not having directionality generated was remarkably large.

From the experiment results, when the pulse-time-modulated plasma using fluorine gas (F₂) as a treatment gas was compared with conventional pulse-time-modulated plasma using sulfur hexa-fluoride gas (SF₆), it was revealed that the amount of F⁻ ion generated is remarkably large while the amount of generated F radical not having polarity, which will cause disturbance in fine processing, is remarkably small. Furthermore, it was revealed that the neutral beam extracted from the pulse-time-modulated plasma using fluorine gas (F₂) as a treatment gas is neutral F beam having uniform directionality, and the anisotropic etching can be realized.

### Comparative Example 4

By the neutral beam generated by selectively extracting negative ions from the pulse-time-modulated plasma using sulfur hexa-fluoride (SF₆) as a treatment gas and neutralizing them, plasma etching for a substrate was carried out. The substrate prepared by depositing a polysilicon (Poly-Si) film having a gate length of 50 nm which length will be desired in the coming generation was used. By comparison with Example 4, it was confirmed that the case of using fluorine gas (F₂) as a treatment gas was superior. The results are shown in FIG. 19.

As is clear from FIG. 19, in the neutral beam generated by selectively extracting negative ions from the pulse-time-modulated plasma of sulfur hexa-fluoride (SF₆) and neutralizing them, clearly large undercut (side etching) was confirmed and it was revealed that the formation of a polysilicon (Poly-Si) pattern in a level of 50 nm cannot be performed. Further, it was also revealed that the etching rate was 18.0 nm/min and was lower as compared with the etching rate (29.4 nm/min) in the above case of using fluorine gas (F₂) (Example 4).

1. A process for plasma treatment which process comprises the steps of:
feeding a treatment gas containing fluorine gas (F₂) into a plasma generating chamber,
alternately repeating application of a high frequency electric field and stop of the application thereof to generate plasma, and
carrying out substrate treatment by irradiating the plasma to a substrate.

2. A process for plasma treatment which process comprises the steps of:
feeding a treatment gas containing fluorine gas (F₂) into a plasma generating chamber,
alternately repeating application of a high frequency electric field and stop of the application thereof to generate plasma,
individually or alternately extracting negative ions or positive ions from the plasma and neutralizing them to generate a neutral beam, and
carrying out substrate treatment by irradiating the neutral beam to a substrate.

3. A process for plasma treatment which process comprises the steps of:
feeding a treatment gas containing fluorine gas (F₂) into a plasma generating chamber,
alternately repeating application of a high frequency electric field and stop of the application thereof to generate plasma,
selectively extracting only negative ions from the plasma and neutralizing them to generate a neutral beam, and
carrying out substrate treatment by irradiating the neutral beam to a substrate.

4. The process for plasma treatment according to claim 1, wherein the treatment gas is 100% by volume of fluorine gas (F₂).

5. The process for plasma treatment according to claim 1, wherein the treatment gas is a mixed gas of fluorine gas (F₂) and chlorine gas Cl₂.

6. The process for plasma treatment according to claim 1, wherein the fluorine gas (F₂) is fluorine gas (F₂) generated by thermally decomposing a solid metal fluoride.

7. The process for plasma treatment according to claim 1, wherein in generating the plasma, the gas pressure of a plasma generating chamber is from 0.1 to 100 Pa.

8. The process for plasma treatment according to claim 1, wherein in generating the plasma, the stop time of application of high frequency electric field is from 20 to 100 μsec.

9. A process for fluorination treatment which process is characterized by utilizing the process for plasma treatment as claimed in claim 1.

10. A process for plasma etching a substrate which process is characterized by utilizing the process for plasma treatment as claimed in claim 1.

11. A process for plasma etching silicon or a silicon compound which process is characterized by utilizing the process for plasma etching as claimed in claim 10.

12. The process for plasma etching according to claim 11 wherein the silicon compound comprises silicon oxide, silicon nitride or a silicate.

13. A semiconductor device produced by the process as claimed in claim 1.

14. A micro machine (MEMS: Micro Electric Mechanical System) device produced by the process as claimed in claim 1.
